(19) United States
(12) Patent Application Publication
(10) Pub. No.: US 2024/0396306 A1
(43) Pub. Date: Nov. 28, 2024

(54) NITRIDE SEMICONDUCTOR LIGHT-EMITTING ELEMENT

(71) Applicant: Nuvoton Technology Corporation Japan, Kyoto (JP)

(72) Inventors: Masayuki HATA, Osaka (JP); Toru TAKAYAMA, Toyama (JP); Shinji YOSHIDA, Shiga (JP); Yasutoshi KAWAGUCHI, Toyama (JP)

(21) Appl. No.: 18/797,149

(22) Filed: Aug. 7, 2024

Related U.S. Application Data
(63) Continuation of application No. PCT/JP2022/041910, filed on Nov. 10, 2022.

(30) Foreign Application Priority Data
Feb. 14, 2022 (JP) 2022-020111

(51) Int. Cl. H01S 5/343; H01S 5/22

(52) U.S. Cl. CPC H01S 5/34346; H01S 5/2205; H01S 5/34333

(57) ABSTRACT

A nitride semiconductor light-emitting element includes: a substrate comprising GaN; a first cladding layer comprising AlGaN and disposed above the substrate; an active layer disposed above the substrate; and a first semiconductor layer interposed between the first cladding layer and the active layer. The active layer includes a well layer comprising a nitride semiconductor, and a barrier layer comprising a nitride semiconductor including Al. The average band gap energy of the first semiconductor layer is smaller than the average band gap energy of the first cladding layer. The first semiconductor layer comprises AlGaInN.

### CROSS REFERENCE TO RELATED APPLICATIONS

This is a continuation application of PCT International Application No. PCT/JP2022/041910 filed on Nov. 10, 2022, designating the United States of America, which is based on and claims priority of Japanese Patent Application No. 2022-020111 filed on Feb. 14, 2022. The entire disclosures of the above-identified applications, including the specifications, drawings and claims are incorporated herein by reference in their entirety.

### FIELD

The present disclosure relates to nitride semiconductor light-emitting elements.

### BACKGROUND

Conventional nitride semiconductor light-emitting elements that emit blue light are known, but there is a demand for high-power nitride semiconductor light-emitting elements that emit ultraviolet light having a shorter wavelength (see PTL 1, for example). If a watt-class ultraviolet laser light source can be achieved, for example, by a nitride semiconductor light-emitting element, a nitride semiconductor light-emitting element can be used in, for instance, a light source for exposure or a light source for processing.

### CITATION LIST

### Patent Literature

PTL 1: Japanese Unexamined Patent Application Publication No. 2010-258363

### SUMMARY

### Technical Problem

For example, an active layer having a quantum well structure is used as the light-emitting layer of a nitride semiconductor light- emitting element that emits ultraviolet light. Such an active layer includes one or more well layers and a plurality of barrier layers. Since ultraviolet light has a shorter wavelength (i.e., larger energy) than visible light, the band gap energy of a well layer that emits ultraviolet light is larger than the band gap energy of a well layer that emits visible light. Therefore, in order to ensure quantum effects in the quantum well structure, it is necessary to increase the band gap energy of a barrier layer. When a GaN substrate, a barrier layer that comprises a nitride semiconductor including Al, and a cladding layer comprising AlGaN are used for a nitride semiconductor light-emitting element, it is necessary to increase the Al composition ratio of the barrier layer to increase the band gap energy of the barrier layer. Since this reduces the refractive index of the barrier layer, it is necessary to increase the Al composition ratio of the cladding layer to reduce the refractive index of the cladding layer to be less than the refractive index of the barrier layer.

By thus increasing the Al composition ratios of the barrier layer and the cladding layer of the nitride semiconductor light-emitting element, tensile strain in the semiconductor stack, such as a cladding layer, with respect to the GaN substrate increases. For this reason, crystallinity in the semiconductor stack deteriorates or the semiconductor stack easily cracks.

The present disclosure overcomes such problems and has an object to provide a nitride semiconductor light-emitting element that can reduce tensile strain in the semiconductor stack with respect to the substrate.

### Solution to Problem

To overcome the above-described problems, a nitride semiconductor light-emitting element according to one aspect of the present disclosure includes: a substrate comprising GaN; a first cladding layer comprising AlGaN and disposed above the substrate; an active layer disposed above the substrate; and a first semiconductor layer interposed between the first cladding layer and the active layer. The active layer includes a well layer comprising a nitride semiconductor, and a barrier layer comprising a nitride semiconductor including Al. The average band gap energy of the first semiconductor layer is smaller than the average band gap energy of the first cladding layer. The first semiconductor layer comprises AlGaInN.

To overcome the above-described problems, a nitride semiconductor light-emitting element according to another aspect of the present disclosure includes: a substrate comprising GaN; an N-type cladding layer comprising AlGaN and disposed above the substrate; an N-side semiconductor layer comprising a nitride semiconductor and disposed above the N-type cladding layer; an active layer disposed above the N-side semiconductor layer; a P-side semiconductor layer comprising a nitride semiconductor and disposed above the active layer; and a P-type cladding layer comprising AlGaN and disposed above the P-side semiconductor layer. The active layer includes a well layer comprising a nitride semiconductor, and a barrier layer comprising a nitride semiconductor including Al. The average band gap energy of the N-side semiconductor layer is smaller than the average band gap energy of the P-side semiconductor layer. The average band gap energy of the P-side semiconductor layer is smaller than the average band gap energy of the P-type cladding layer. At least one of the N-side semiconductor layer or the P-side semiconductor layer comprises AlGaInN.

### Advantageous Effects

The present disclosure can provide a nitride semiconductor light-emitting element that can reduce tensile strain in the semiconductor stack with respect to the substrate.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a schematic plan view of the overall configuration of a nitride semiconductor light-emitting element according to Embodiment 1.

FIG. 2A is a schematic cross-sectional view of the overall configuration of the nitride semiconductor light-emitting element according to Embodiment 1.

FIG. 2B is a schematic cross-sectional view of the configuration of the active layer included in the nitride semiconductor light-emitting element according to Embodiment 1.

FIG. 3 is a graph showing a distribution of the band gap energy of a semiconductor stack according to Embodiment 1 in the stacking direction of the semiconductor stack.

FIG. 4 is a graph showing the relationship between band gap energy in an AlₓGa_{1-x-y}In_{y}N layer and band gap energy in an Al_{z}Ga_{1-z}N layer.

FIG. 5 is a graph showing a distribution of the band gap energy of a semiconductor stack according to Embodiment 2 in the stacking direction of the semiconductor stack.

FIG. 6 is a graph showing a distribution of the band gap energy of a semiconductor stack according to Embodiment 3 in the stacking direction of the semiconductor stack.

FIG. 7 is a graph showing a distribution of the band gap energy of a semiconductor stack according to Embodiment 4 in the stacking direction of the semiconductor stack.

FIG. 8 is a graph showing a distribution of the band gap energy of a semiconductor stack according to Embodiment 5 in the stacking direction of the semiconductor stack.

FIG. 9 is a graph showing a distribution of the band gap energy of a semiconductor stack according to Embodiment 6 in the stacking direction of the semiconductor stack.

FIG. 10 is a graph showing a distribution of the band gap energy of a semiconductor stack according to Embodiment 7 in the stacking direction of the semiconductor stack.

FIG. 11 is a graph showing a distribution of the band gap energy of a semiconductor stack according to Embodiment 8 in the stacking direction of the semiconductor stack.

FIG. 12 is a graph showing a distribution of the band gap energy of a semiconductor stack according to Embodiment 9 in the stacking direction of the semiconductor stack.

FIG. 13 is a graph showing a distribution of the band gap energy of a semiconductor stack according to Embodiment 10 in the stacking direction of the semiconductor stack.

FIG. 14 is a graph showing a distribution of the band gap energy of a semiconductor stack according to Embodiment 11 in the stacking direction of the semiconductor stack.

FIG. 15 is a graph showing a distribution of the band gap energy of a semiconductor stack according to Embodiment 12 in the stacking direction of the semiconductor stack.

FIG. 16 is a graph showing a distribution of the band gap energy of a semiconductor stack according to Embodiment 13 in the stacking direction of the semiconductor stack.

### DESCRIPTION OF EMBODIMENTS

Hereinafter, embodiments of the present disclosure will be described in detail with reference to the drawings. Note that each of the embodiments described below shows a specific example of the present disclosure. Therefore, numerical values, shapes, materials, elements, the arrangement and connectivity of the elements, etc., indicated in the following embodiments are mere examples and are not intended to limit the present disclosure.

The figures are schematic diagrams and are not necessarily precise illustrations. Accordingly, the figures are not necessarily to scale. Substantially identical elements in the drawings are assigned with the same reference signs, and redundant description is omitted or simplified.

In this Specification, the terms “above” and “below” do not refer to a vertically upward direction and a vertically downward direction in terms of absolute spatial recognition, but are used as terms defined by relative positional relationships based on the stacking order in a stacked configuration. The terms “above” and “below” are applied not only when two elements are disposed with a gap therebetween and a separate element is interposed between the two elements, but also when two elements are disposed in contact with each other.

### Embodiment 1

A nitride semiconductor light-emitting element according to Embodiment 1 will be described.

### [1-1. Overall Configuration]

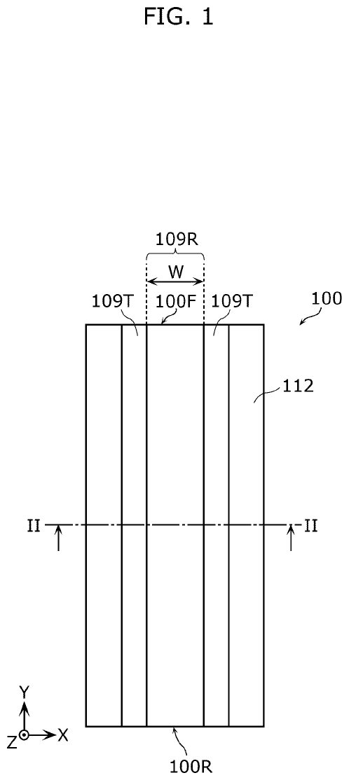

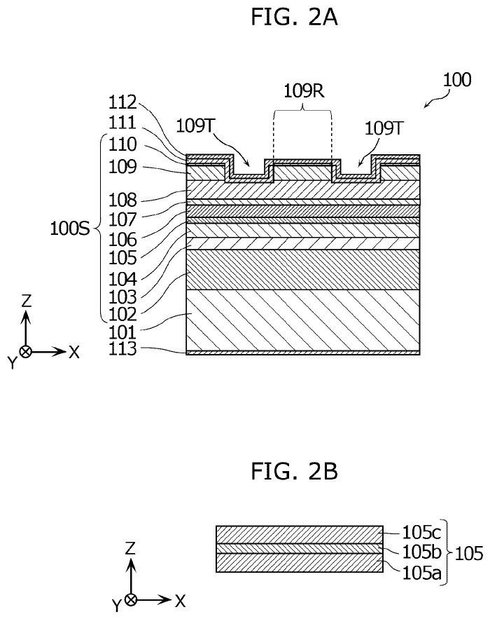

First, the overall configuration of the nitride semiconductor light-emitting element according to the present embodiment will be described with reference to FIG. 1, FIG. 2A, and FIG. 2B. FIG. 1 and FIG. 2A are a schematic plan view and a schematic cross-sectional view, respectively, of the overall configuration of nitride semiconductor light-emitting element 100 according to the present embodiment. FIG. 2A illustrates a cross section taken at line II-II in FIG. 1. FIG. 2B is a schematic cross-sectional view of the configuration of active layer 105 included in nitride semiconductor light-emitting element 100 according to the present embodiment. Each figure shows an X-axis, a Y-axis, and a Z-axis that are orthogonal to each other. The X-axis, Y-axis, and Z-axis are axes in a right-handed orthogonal coordinate system. The stacking direction of nitride semiconductor light-emitting element 100 is parallel to the Z-axis direction, and the main emission direction of light (a laser beam) is parallel to the Y-axis direction.

As illustrated in FIG. 2A, nitride semiconductor light-emitting element 100 includes semiconductor stack 100S including nitride semiconductor layers, and emits light from end face 100F (see FIG. 1) of semiconductor stack 100S in a direction perpendicular to the stacking direction (i.e., the Z-axis direction) of semiconductor stack 100S. In the present embodiment, nitride semiconductor light-emitting element 100 is a semiconductor laser element including two end faces 100F and 100R forming a resonator. End face 100F is the front end face from which the laser beam is emitted, and end face 100R is the rear end face having a higher reflectance than end face 100F. Nitride semiconductor light-emitting element 100 includes a waveguide formed between end face 100F and end face 100R. In the present embodiment, the reflectance of end face 100F is 16% and the reflectance of end face 100R is 95%. The resonator length (i.e., the distance between end face 100F and end face 100R) of nitride semiconductor light-emitting element 100 according to the present embodiment is approximately 1200 μm. Nitride semiconductor light-emitting element 100 emits, for example, ultraviolet light having a peak wavelength in the 375 nm band. Nitride semiconductor light-emitting element 100 may emit ultraviolet light having a peak wavelength in a band other than the 375 nm band or light having a peak wavelength in a wavelength band other than the wavelength band of ultraviolet light.

As illustrated in FIG. 2A, nitride semiconductor light-emitting element 100 includes substrate 101, semiconductor stack 100S, current blocking layer 111, P-side electrode 112, and N-side electrode 113. Semiconductor stack 100S includes N-type cladding layer 102, first N-side guide layer 103, second N-side guide layer 104, active layer 105, first P-side guide layer 106, electron blocking layer 107, second P-side guide layer 108, P-type cladding layer 109, and contact layer 110.

Substrate 101 is a plate-shaped member that serves as the base of nitride semiconductor light-emitting element 100. In the present embodiment, substrate 101 is disposed below N-type cladding layer 102 and comprises N-type GaN. More specifically, substrate 101 is a GaN substrate doped with Si at a concentration of 1×10¹⁸ cm⁻³.

N-type cladding layer 102 is one example of a first cladding layer that comprises AlGaN and is disposed above substrate 101. A cladding layer is a layer in which how a light intensity distribution inside the layer in the stacking direction changes can be approximated using an exponential function. The conductivity type of N-type cladding layer 102 is N type. N-type cladding layer 102 has a lower refractive index and larger average band gap energy than active layer 105. In the present embodiment, N-type cladding layer 102 is an N-type Al_{0.065}Ga_{0.935}N layer that has a thickness of 800 nm and is doped with Si at a concentration of 5×10¹⁷ cm⁻³.

In the present disclosure, the average band gap energy of a given layer is a band gap energy value obtained by integrating, in the stacking direction of that layer, the amount of band gap energy at a given location in the layer in the stacking direction from the location of an interface close to the substrate to the location of an interface far from the substrate in the stacking direction of the layer, and dividing the resulting value by the thickness of the layer (the distance between the interface close to the substrate and the interface far from the substrate).

The average refractive index of a given layer is a refractive index value obtained by integrating, in the stacking direction of that layer, a refractive index at a given location in the layer in the stacking direction from the location of an interface close to the substrate to the location of an interface far from the substrate in the stacking direction, and dividing the resulting value by the thickness of the layer (the distance between the interface close to the substrate and the interface far from the substrate).

The average Al composition ratio of a given layer is an Al composition ratio value obtained by integrating, in the stacking direction of that layer, an Al composition ratio at a given location in the layer from the location of an interface close to the substrate to the location of an interface far from the substrate in the stacking direction, and dividing the resulting value by the thickness of the layer (the distance between the interface close to the substrate and the interface far from the substrate).

The average impurity concentration of a given layer is an impurity concentration value obtained by integrating, in the stacking direction of that layer, an impurity concentration value at a given location in the layer in the stacking direction from the location of an interface close to the substrate to the location of an interface far from the substrate in the stacking direction, and dividing the resulting value by the thickness of the layer (the distance between the interface close to the substrate and the interface far from the substrate). In an N-type semiconductor layer, an impurity means an impurity that is doped to obtain the conductivity type of N type, and in a P-type semiconductor layer, an impurity means an impurity that is doped to obtain the conductivity type of P type.

First N-side guide layer 103 is one example of a first guide layer that is an optical guide layer disposed between N-type cladding layer 102 and active layer 105, and comprises a nitride semiconductor. The optical guide layer is a layer in which how the light intensity distribution in the layer in the stacking direction changes can be approximated using a trigonometric function. First N-side guide layer 103 has a higher refractive index and smaller band gap energy than N-type cladding layer 102. The average band gap energy of first N-side guide layer 103 is larger than or equal to the average band gap energy of second N-side guide layer 104. First N-side guide layer 103 includes Al. First N-side guide layer 103 is an N-type nitride semiconductor layer. In other words, the average impurity concentration of first N-side guide layer 103 is 1×10¹⁷ cm⁻³ or higher. In the present embodiment, first N-side guide layer 103 is an N-type Al_{0.03}Ga_{0.97}N layer that has a thickness of 70 nm, is doped with Si at a concentration of 5×10¹⁷ cm⁻³, and is disposed between N-type cladding layer 102 and second N-side guide layer 104.

Second N-side guide layer 104 is one example of an N-side semiconductor layer that comprises a nitride semiconductor and is disposed above N-type cladding layer 102. In the present embodiment, second N-side guide layer 104 is also one example of a first semiconductor layer that comprises AlGaInN and is disposed between N-type cladding layer 102 and active layer 105. In the present embodiment, the average band gap energy of second N-side guide layer 104 is smaller than the average band gap energy of N-type cladding layer 102. Second N-side guide layer 104 is an undoped AlGaInN layer. Stated differently, the average impurity concentration of second N-side guide layer 104 is less than 1×10¹⁷ cm⁻³. In the present embodiment, second N-side guide layer 104 is an undoped Al_{0.05}Ga_{0.94}In_{0.01}N layer that has a thickness of 70 nm and is disposed between first N-side guide layer 103 and active layer 105.

Active layer 105 is a light-emitting layer disposed above substrate 101. In the present embodiment, active layer 105 is disposed above second N-side guide layer 104. Active layer 105 has a quantum well structure and emits ultraviolet light. Specifically, active layer 105 has a single quantum well structure that includes well layer 105b comprising a nitride semiconductor and two barrier layers 105a and 105c each of which comprises a nitride semiconductor including Al, as illustrated in FIG. 2B. Well layer 105b is disposed between two barrier layers 105a and 105c. The structure of active layer 105 is not limited to this example. For example, active layer 105 may have a multiple quantum well structure. Specifically, active layer 105 may have three or more barrier layers and two or more well layers.

Each of barrier layers 105a and 105c is a nitride semiconductor layer that functions as a barrier in the quantum well structure and is disposed above first N-side guide layer 103. Barrier layer 105c is disposed above barrier layer 105a. In the present embodiment, the band gap energy of each of barrier layers 105a and 105c is larger than the band gap energy of well layer 105b, the average band gap energy of first P-side guide layer 106, and the average band gap energy of first N-side guide layer 103, and is smaller than the average band gap energy of electron blocking layer 107. Each of barrier layers 105a and 105c is an undoped Al_{0.07}Ga_{0.92}In_{0.01}N layer with a thickness of 10 nm, and the average band gap energy, the Al composition ratio, and the In composition ratio of barrier layer 105a are respectively the same as the average band gap energy, the Al composition ratio, and the In composition ratio of barrier layer 105c.

Well layer 105b is a nitride semiconductor layer that functions as a well in the quantum well structure and is disposed above barrier layer 105a. In the present embodiment, well layer 105b is an undoped In_{0.01}Ga_{0.99}N layer with a thickness of 17.5 nm.

First P-side guide layer 106 is one example of a P-side semiconductor layer that comprises a nitride semiconductor and is disposed above active layer 105. In the present embodiment, first P-side guide layer 106 is also one example of a first semiconductor layer that comprises AlGaInN and is disposed between P-type cladding layer 109 and active layer 105. In other words, in nitride semiconductor light-emitting element 100, both of second N-side guide layer 104 (i.e., an N-side semiconductor layer) and first P-side guide layer 106 (i.e., a P-side semiconductor layer) comprise AlGaInN. In the present embodiment, first P-side guide layer 106 is an optical guide layer. The band gap energy, the Al composition ratio, and the In composition ratio of first P-side guide layer 106 are respectively the same as the band gap energy, the Al composition ratio, and the In composition ratio of second N-side guide layer 104. The average band gap energy of first P-side guide layer 106 is smaller than the average band gap energy of P-type cladding layer 109. First P-side guide layer 106 is an undoped AlGaInN layer. Stated differently, the average impurity concentration of first P-side guide layer 106 is less than 1×10¹⁸ cm⁻³. In the present embodiment, first P-side guide layer 106 is an undoped Al_{0.05}Ga_{0.94}In_{0.01}N layer with a thickness of 72 nm.

Electron blocking layer 107 is a nitride semiconductor layer disposed between first P-side first guide layer 106 and P-type cladding layer 109. The band gap energy of electron blocking layer 107 is larger than the band gap energy of barrier layer 105c. This can inhibit leakage of electrons from active layer 105 to P-type cladding layer 109. In the present embodiment, the band gap energy of electron blocking layer 107 is larger than the band gap energy of P-type cladding layer 109. Electron blocking layer 107 is a P-type Al_{0.30}Ga_{0.70}N layer that has a thickness of 5 nm and is doped with Mg at a concentration of 1×10¹⁹ cm⁻³.

Second P-type guide layer 108 is one example of a first guide layer that is an optical guide layer disposed between P-type cladding layer 109 and active layer 105, and comprises a nitride semiconductor. Second P-side guide layer 108 is also one example of a second guide layer disposed between electron blocking layer 107 and P-type cladding layer 109. The average band gap energy and the Al composition ratio of second P-side guide layer 108 are respectively the same as the average band gap energy and the Al composition ratio of first N-side guide layer 103. Second P-side guide layer 108 has a higher refractive index and smaller band gap energy than P-type cladding layer 109. The average band gap energy of second P-side guide layer 108 is larger than or equal to the average band gap energy of first P-side guide layer 106. Second P-side guide layer 108 includes Al. Second P-side guide layer 108 is a P-type nitride semiconductor layer. Stated differently, the average impurity concentration of second P-side guide layer 108 is 1×10¹⁸ cm⁻³ or higher. In the present embodiment, second P-side guide layer 108 is a P-type Al_{0.03}Ga_{0.97}N layer that has a thickness of 148 nm, is doped with Mg at a concentration of 1×10¹⁸ cm⁻³, and is disposed between electron blocking layer 107 and P-type cladding layer 109.

P-type cladding layer 109 is one example of a first cladding layer that comprises AlGaN and is disposed above substrate 101. The conductivity type of P-type cladding layer 109 is P type. In the present embodiment, P-type cladding layer 109 is disposed above first P-side guide layer 106. P-type cladding layer 109 has a lower refractive index and larger average band gap energy than active layer 105. The average band gap energy of P-type cladding layer 109 is smaller than the average band gap energy of electron blocking layer 107. The average band gap energy and the Al composition ratio of P-type cladding layer 109 are respectively the same as the average band gap energy and the Al composition ratio of N-type cladding layer 102. In the present embodiment, P-type cladding layer 109 is doped with Mg as an impurity. The impurity concentration of P-type cladding layer 109 is lower in an end portion close to active layer 105 than in an end portion far from active layer 105. Specifically, P-type cladding layer 109 is an AlGaN layer with a thickness of 450 nm and includes: a P-type Al_{0.065}Ga_{0.935}N layer that has a thickness of 150 nm, is doped with Mg at a concentration of 2×10¹⁸ cm³, and is disposed on the side close to active layer 105; and a P-type Al_{0.065}Ga_{0.935}N layer that has a thickness of 300 nm, is doped with Mg at a concentration of 1×10¹⁹ cm⁻³, and is disposed on the side far from active layer 105.

Ridge 109R is formed in P-type cladding layer 109. In addition, two trenches 109T disposed along ridge 109R and extending along the Y-axis direction are also formed in P-type cladding layer 109. In the present embodiment, ridge width W is approximately 30 μm.

Contact layer 110 is a nitride semiconductor layer that is in ohmic contact with P-side electrode 112 and is disposed above P-type cladding layer 109. In the present embodiment, contact layer 110 is a P-type GaN layer with a thickness of 60 nm. Contact layer 110 is doped with Mg at a concentration of 1×10²⁰ cm⁻³ as an impurity.

Current blocking layer 111 is an insulating layer that is light-transmissive with respect to light from active layer 105 and is disposed above P-type cladding layer 109. Current blocking layer 111 is disposed in an area other than the top surface of ridge 109R out of the top surface of P-type cladding layer 109 and the top surface of contact layer 110. Current blocking layer 111 may be disposed also in an area that is a part of the top surface of ridge 109R. For example, current blocking layer 111 may be disposed in an edge area of the top surface of ridge 109R. In the present embodiment, current blocking layer 111 is a SiO₂ layer.

P-side electrode 112 is a conductive layer disposed above contact layer 110. In the present embodiment, P-side electrode 112 is disposed above contact layer 110 and current blocking layer 111. P-side electrode 112 is, for example, a single-layer or multilayer film formed of at least one of Cr, Ti, Ni, Pd, Pt, or Au.

N-side electrode 113 is a conductive layer disposed below substrate 101 (i.e., on the main surface of substrate 101 opposite the main surface of substrate 101 where, for instance, N-type cladding layer 102 of substrate 101 is disposed). N-side electrode 113 is, for example, a single-layer or multilayer film formed of at least one of Cr, Ti, Ni, Pd, Pt, or Au.

Due to nitride semiconductor light-emitting element 100 having the above configuration, there is an effective refractive index difference ΔN between the portion below ridge 109R and the portions below trenches 109T. This allows the light generated in the portion of active layer 105 below ridge 109R to be confined in the horizontal direction (i.e., in the X-axis direction).

### [1-2. Advantageous Effects]

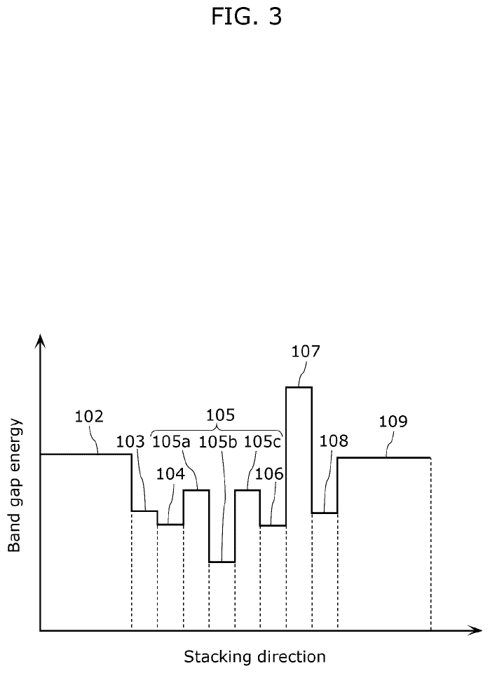

Advantageous effects of nitride semiconductor light-emitting element 100 according to the present embodiment will be described with reference to FIG. 3. FIG. 3 is a graph showing a distribution of the band gap energy of semiconductor stack 100S according to the present embodiment in the stacking direction of semiconductor stack 100S. In FIG. 3, the horizontal axis indicates a location in the stacking direction and the right side of the horizontal axis corresponds to the upper side of semiconductor stack 100S. In FIG. 3, contact layer 110 is omitted.

The band gap energy of a well layer which emits ultraviolet light, like well layer 105b of nitride semiconductor light-emitting element 100 according to the present embodiment, is larger than the band gap energy of a well layer that emits visible light. For this reason, it is necessary to increase the band gap energy of a barrier layer. For example, when a GaN substrate, a barrier layer comprising AlGaInN, and a cladding layer comprising AlGaN are used for a nitride semiconductor light-emitting element, it is necessary to increase the Al composition ratio of the barrier layer in order to increase the band gap energy of the barrier layer. Since this reduces the refractive index of the barrier layer, it is necessary to increase the Al composition ratio of the cladding layer to reduce the refractive index of the cladding layer to be lower than the refractive index of the barrier layer. Thus, with the increase of the Al composition ratios of the barrier layer and the cladding layer of the nitride semiconductor light-emitting element, tensile strain in the semiconductor stack, such as a cladding layer, with respect to the GaN substrate increases. For this reason, crystallinity in the semiconductor stack deteriorates or the semiconductor stack easily cracks.

In contrast, with nitride semiconductor light-emitting element 100 according to the present embodiment, since second N-side guide layer 104 and first P-side guide layer 106 comprise AlGaInN, as illustrated in FIG. 3, it is possible to reduce tensile strain with respect to substrate 101 while maintaining the same band gap energy and the same refractive index, compared with when second N-side guide layer 104 and first P-side guide layer 106 comprise AlGaN. Accordingly, it is possible to achieve nitride semiconductor light-emitting element 100 that can reduce tensile strain in semiconductor stack 100S with respect to substrate 101. This can inhibit deterioration of crystallinity in semiconductor stack 100S and cracks in semiconductor stack 100S.

In addition, reducing the tensile strain in semiconductor stack 100S on substrate 101 can reduce a piezoelectric field from active layer 105 to electron blocking layer 107. Since this piezoelectric field may serve as a barrier for holes, efficiency of hole injection can be enhanced by reducing the piezoelectric field.

As described above, in the present embodiment, it is possible to reduce the piezoelectric field while ensuring the optical confinement factor of nitride semiconductor light-emitting element 100.

In the present embodiment, the refractive index of second P-side guide layer 108 can be reduced to be lower than the refractive index of first P-side guide layer 106 by increasing the band gap energy of second P-side guide layer 108 above electron blocking layer 107 to be larger than the band gap energy of first P-side guide layer 106. This can bring the peak position of a light intensity distribution in the stacking direction closer to the center of active layer 105 in the stacking direction. In other words, it is possible to increase the optical confinement factor of nitride semiconductor light-emitting element 100.

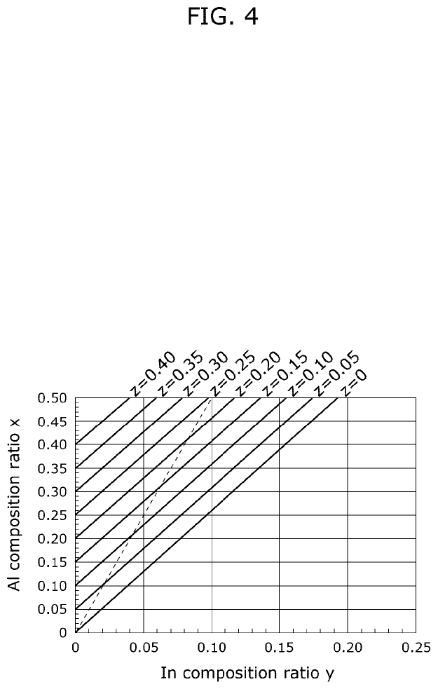

An AlGaInN composition determination method will be described with reference to FIG. 4. FIG. 4 is a graph showing the relationship between band gap energy in an AlₓGa_{1-x-y}In_{y}N layer and band gap energy in an Al_{z}Ga_{1-z}N layer. In FIG. 4, the horizontal axis indicates In composition ratio y in the AlₓGa_{1-x-y}In_{y}N layer and the vertical axis indicates Al composition ratio x in the AlₓGa_{1-x-y}In_{y}N layer. FIG. 4 shows the relationship between In composition ratio y and Al composition ratio x for obtaining the band gap energy of the AlₓGa_{1-x-y}In_{y}N layer that is same as the band gap energy of the Al_{z}Ga_{1-z}N layer. FIG. 4 shows the relationship in each of the cases where the Al composition ratio z of the Al_{z}Ga_{1-z}N layer is 0, 0.05, 0.10, 0.15, 0.20, 0.25, 0.30, 0.35, and 0.40. In FIG. 4, a dashed line shows the relationship between In composition ratio y and Al composition ratio x for equalizing the lattice constant of the AlₓGa_{1-x-y}In_{y}N layer and the lattice constant of the GaN layer. Accordingly, the upper left area above the dashed line in the graph in FIG. 4 shows a composition ratio whose lattice constant of the AlₓGa_{1-x-y}In_{y}N layer is smaller than the lattice constant of the GaN layer, while the lower right area below the dashed line shows a composition ratio whose lattice constant of the AlₓGa_{1-x-y}In_{y}N layer is greater than the lattice constant of the GaN layer. In the lattice constant calculation, 0.311 nm is used as the lattice constant of AlN, 0.3182 nm is used as the lattice constant of GaN, and 0.354 nm is used as the lattice constant of InN.

To obtain the band gap energy of the AlₓGa_{1-x-y}In_{y}N layer that is same as the band gap energy of the Al_{z}Ga_{1-z}N layer, the following equation (1) needs to hold true as illustrated in FIG. 4.

$$x = ( - 0.1727 z + 2.5 \; 95 ) y + z \qquad ( 1 )$$

It is thus possible to replace an AlGaN layer with an AlGaInN layer while keeping the band gap energy of the AlGaN layer.

In the present embodiment, barrier layers 105a and 105c comprise AlGaInN. This can reduce tensile strain in barrier layers 105a and 105c with respect to substrate 101, as described above. Accordingly, it is possible to reduce tensile strain in semiconductor stack 100S with respect to substrate 101 as well as increase internal quantum efficiency and reduce the long wavelength shift of an oscillation wavelength. In addition, with barrier layer 105a, which is located below well layer 105b, including In, the crystallinity of well layer 105b stacked on barrier layer 105a can be enhanced.

In the present embodiment, the ratio of the In composition ratio to the Al composition ratio (y/x) of barrier layer 105a is less than the ratio of the In composition ratio to the Al composition ratio (y/x) of second N-side guide layer 104. This reduces the band gap energy of second N-side guide layer 104 to be smaller than the band gap energy of barrier layer 105a and increases the refractive index of second N-side guide layer 104 to be higher than the refractive index of barrier layer 105a. By thus increasing the band gap energy of barrier layer 105c, quantum effect in the quantum well structure can be enhanced. In addition, the peak position of the light intensity distribution in the stacking direction can be brought closer to the center of active layer 105 in the stacking direction by bringing second N-side guide layer 104, which has a high refractive index, next to active layer 105. In other words, the optical confinement factor of nitride semiconductor light-emitting element 100 can be increased.

Likewise, the ratio of the In composition ratio to the Al composition ratio (y/x) of barrier layer 105c is less than the ratio of the In composition ratio to the Al composition ratio (y/x) of first P-side guide layer 106. This reduces the band gap energy of first P-side guide layer 106 to be smaller than the band gap energy of barrier layer 105c, and increases the refractive index of first P-side guide layer 106 to be higher than the refractive index of barrier layer 105c. By thus increasing the band gap energy of barrier layer 105c, quantum effect in the quantum well structure can be enhanced. In addition, the peak position of the light intensity distribution in the stacking direction can be brought closer to the center of active layer 105 in the stacking direction by bringing first P-side guide layer 106, which has a high refractive index, next to active layer 105. In other words, the optical confinement factor of nitride semiconductor light-emitting element 100 can be increased.

In the present embodiment, since second N-side guide layer 104 comprising AlGaInN is disposed below well layer 105b, fluctuation of the In composition ratio of well layer 105b is likely to be generated. Since this causes localization of carriers in well layer 105b, light emission efficiency improves.

In the present embodiment, since first P-side guide layer 106 is an undoped layer, diffusion of Mg to active layer 105 can be inhibited. In addition, since first P-side guide layer 106 comprises AlGaInN, diffusion of Mg from electron blocking layer 107, which has a high Mg concentration, to active layer 105 can be inhibited. Accordingly, it is possible to reduce light absorption loss, caused by Mg, in active layer 105 and in the vicinity thereof. This can inhibit an increase in the threshold value current of laser oscillation and a reduction in light emission efficiency in nitride semiconductor light-emitting element 100.

Since inhibiting the diffusion of Mg from electron blocking layer 107 to active layer 105 can inhibit an increase in electrical resistance in electron blocking layer 107, it is possible to inhibit an increase in the operation voltage of nitride semiconductor light-emitting element 100.

Furthermore, since diffusion of hydrogen caused by the diffusion of Mg can be also inhibited, reliability of nitride semiconductor light-emitting element 100 can be enhanced.

In the present embodiment, since second N-side guide layer 104 and first P-side guide layer 106 that are optical guide layers comprise AlGaInN, tensile strain in semiconductor stack 100S with respect to substrate 101 can be reduced even when the thickness of the optical guide layers is increased. Alternatively, the tensile strain in semiconductor stack 100S with respect to substrate 101 can be reduced even when the refractive index of second N-side guide layer 104 and the refractive index of first P-side guide layer 106 that are optical guide layers are reduced.

Nitride semiconductor light-emitting element 100 according to the present embodiment includes first N-side guide layer 103 and second P-side guide layer 108 in addition to second N-side guide layer 104 and first P-side guide layer 106. Thus, even in a configuration in which the total thickness of the optical guide layers is large, it is possible to reduce the tensile strain in semiconductor stack 100S with respect to substrate 101 since second N-side guide layer 104 and first P-side guide layer 106 comprise AlGaInN.

Nitride semiconductor light-emitting element 100 according to the present embodiment having electron blocking layer 107 between first P-side guide layer 106 and second P-side guide layer 108 can confine electrons in a narrow area near active layer 105 compared with when electron blocking layer 107 is disposed above second P-side guide layer 108. Nitride semiconductor light-emitting element 100 according to the present embodiment having second P-side guide layer 108 disposed above electron blocking layer 107 can bring the peak position of a light intensity distribution in the stacking direction closer to the center of active layer 105 in the stacking direction compared with when nitride semiconductor light-emitting element 100 does not include second P-side guide layer 108.

### [1-3. Manufacturing Method]

A method of manufacturing nitride semiconductor light-emitting element 100 according to the present embodiment will be described.

Nitride semiconductor light-emitting element 100 according to the present embodiment is manufactured by sequentially forming semiconductor stack 100S, current blocking layer 111, and P-side electrode 112 on substrate 101 and forming N-side electrode 113 on the main surface of substrate 101 that is the rear side of the main surface on which semiconductor stack 100S is formed.

Semiconductor stack 100S is stacked on substrate 101 using epitaxial growth technologies based on a metal organic chemical vapor deposition (MOCVD) method. In semiconductor stack 100S according to the present embodiment, each of layers (N-type cladding layer 102, first N-side guide layer 103, electron blocking layer 107, second P-side guide layer 108, P-type cladding layer 109, and contact layer 110) comprising AlGaN crystal grows at, for example, 1150 degrees Celsius. Each of layers (second N-side guide layer 104, active layer 105, and first P-side guide layer 106) comprising In crystal grows at, for example, 850 degrees Celsius. Each of the layers comprising In crystal grows at a lower growth speed than each of the layers comprising AlGaN. In the semiconductor stack according to each of the following embodiments, each of layers comprising AlGaN crystal grows at 1150 degrees Celsius and each of layers comprising In crystal grows at 850 degrees Celsius.

Patterning is performed on, for instance, P-type cladding layer 109 in semiconductor stack 100S where necessary using photolithography technology, etching, etc.

Current blocking layer 111 is formed using, for example, a plasma CVD method or the like, and patterning is performed where necessary using photolithography technology, etching, etc.

P-side electrode 112 and N-side electrode 113 are formed using photolithography technology and a vapor deposition method.

Nitride semiconductor light-emitting element 100 according to the present embodiment can be manufactured using the above manufacturing method.

### Embodiment 2

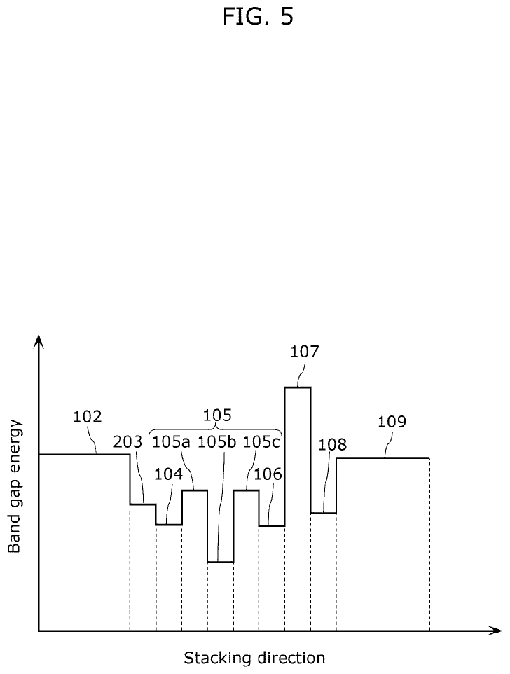

A nitride semiconductor light-emitting element according to Embodiment 2 will be described. The nitride semiconductor light-emitting element according to the present embodiment differs from nitride semiconductor light-emitting element 100 according to Embodiment 1 in regard to the configuration of a first N-side guide layer. The nitride semiconductor light-emitting element according to the present embodiment will be described with reference to FIG. 5, focusing on the difference from nitride semiconductor light-emitting element 100 according to Embodiment 1. FIG. 5 is a graph showing a distribution of the band gap energy of a semiconductor stack according to the present embodiment in the stacking direction of the semiconductor stack.

The nitride semiconductor light-emitting element according to the present embodiment, like nitride semiconductor light-emitting element 100 according to Embodiment 1, includes substrate 101, the semiconductor stack, current blocking layer 111, P-side electrode 112, and N-side electrode 113. As illustrated in FIG. 5, the semiconductor stack according to the present embodiment includes N-type cladding layer 102, first N-side guide layer 203, second N-side guide layer 104, active layer 105, first P-side guide layer 106, electron blocking layer 107, second P-side guide layer 108, P-type cladding layer 109, and contact layer 110 (see FIG. 2A).

First N-side guide layer 203 according to the present embodiment is one example of a first guide layer that is an optical guide layer disposed between N-type cladding layer 102 and active layer 105, and comprises AlGaInN. In other words, first N-side guide layer 203 is also one example of a first semiconductor layer and is also one example of an N-side semiconductor layer. First N-side guide layer 203 has a higher refractive index and smaller band gap energy than N-type cladding layer 102. First N-side guide layer 203 is an N-type nitride semiconductor layer. The average band gap energy of first N-side guide layer 203 is larger than the average band gap energy of second P-side guide layer 108. In the present embodiment, first N-side guide layer 203 is an N-type Al_{0.06}Ga_{0.93}In_{0.01}N layer that has a thickness of 70 nm, is doped with Si at a concentration of 5×10¹⁷ cm⁻³, and is disposed between N-type cladding layer 102 and second N-side guide layer 104.

With the nitride semiconductor light-emitting element according to the present embodiment, since first N-side guide layer 203 comprises AlGaInN, tensile strain in the semiconductor stack with respect to substrate 101 can be further reduced.

The semiconductor stack according to the present embodiment, like semiconductor stack 100S according to Embodiment 1, is stacked on substrate 101 using epitaxial growth technologies based on the MOCVD method. In semiconductor stack 100S according to the present embodiment, each of layers (N-type cladding layer 102, electron blocking layer 107, second P-side guide layer 108, P-type cladding layer 109, and contact layer 110) comprising AlGaN crystal grows at, for example, 1150 degrees Celsius. Each of layers (first N-side guide layer 203, second N-side guide layer 104, active layer 105, and first P-side guide layer 106) comprising In crystal grows at, for example, 850 degrees Celsius at a lower growth speed than each of the layers comprising AlGaN.

### Embodiment 3

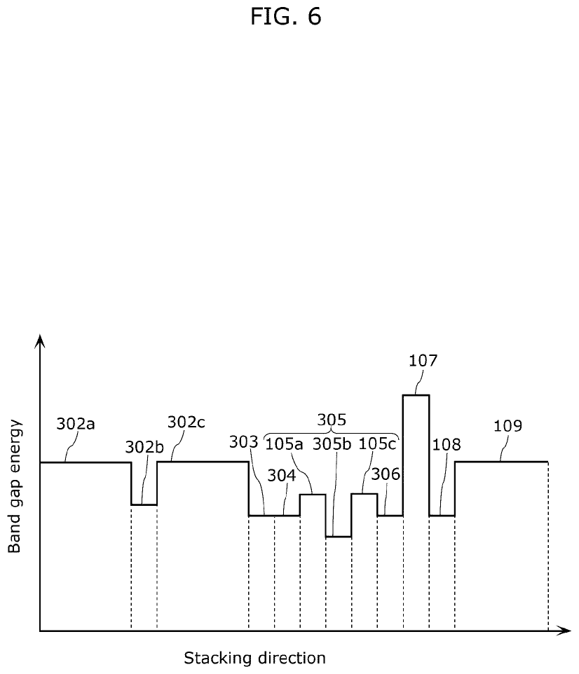

A nitride semiconductor light-emitting element according to Embodiment 3 will be described. The nitride semiconductor light-emitting element according to the present embodiment differs from nitride semiconductor light-emitting element 100 according to Embodiment 1 in regard to the configurations of an N-type cladding layer, an optical guide layer, and a well layer. Hereinafter, the nitride semiconductor light-emitting element according to the present embodiment will be described with reference to FIG. 6, focusing on the difference from nitride semiconductor light-emitting element 100 according to Embodiment 1. FIG. 6 is a graph showing a distribution of the band gap energy of a semiconductor stack according to the present embodiment in the stacking direction of the semiconductor stack.

The nitride semiconductor light-emitting element according to the present embodiment, like nitride semiconductor light-emitting element 100 according to Embodiment 1, includes substrate 101, the semiconductor stack, current blocking layer 111, P-side electrode 112, and N-side electrode 113. As illustrated in FIG. 6, the semiconductor stack according to the present embodiment includes first N-type cladding layer 302a, second N-type cladding layer 302b, third N-type cladding layer 302c, first N-side guide layer 303, second N-side guide layer 304, active layer 305, first P-side guide layer 306, electron blocking layer 107, second P-side guide layer 108, P-type cladding layer 109, and contact layer 110 (see FIG. 2A). Active layer 305 includes two barrier layers 105a and 105c, and well layer 305b.

First N-type cladding layer 302a according to the present embodiment is one example of a first cladding layer that comprises AlGaN and is disposed above substrate 101, and is also one example of an N-type cladding layer. The conductivity type of first N-type cladding layer 302a is N type. First N-type cladding layer 302a has a lower refractive index and larger average band gap energy than active layer 305. In the present embodiment, first N-type cladding layer 302a is an N-type Al_{0.065}Ga_{0.935}N layer that has a thickness of 350 nm, is doped with Si at a concentration of 5×10¹⁷ cm⁻³, and is disposed between substrate 101 and second N-type cladding layer 302b.

Second N-type cladding layer 302b is one example of a first semiconductor layer that comprises AlGaInN and is disposed between first N-type cladding layer 302a and active layer 305, and is also one example of an N-side semiconductor layer. Second N-type cladding layer 302b is an N-type cladding layer. The average band gap energy of second N-type cladding layer 302b is smaller than the average band gap energy of first N-type cladding layer 302a and the band gap energy of barrier layer 105a. The Al composition ratio of second N-type cladding layer 302b is higher than the Al composition ratio of first N-type cladding layer 302a. In the present embodiment, second N-type cladding layer 302b is an N-type Al_{0.17}Ga_{0.78}In_{0.05}N layer that has a thickness of 100 nm, is doped with Si at a concentration of 5×10¹⁷ cm⁻³, and is disposed between first N-type cladding layer 302a and third N-type cladding layer 302c.

Third N-type cladding layer 302c is one example of a first cladding layer that comprises AlGaN and is disposed above substrate 101, and is also one example of an N-type cladding layer. Third N-type cladding layer 302c has a lower refractive index and larger average band gap energy than active layer 305. In the present embodiment, third N-type cladding layer 302c is an N-type Al_{0.065}Ga_{0.935}N layer that has a thickness of 350 nm, is doped with Si at a concentration of 5×10¹⁷ cm⁻³, and is disposed between second N-type cladding layer 302b and first N-side guide layer 303.

First N-side guide layer 303 is one example of a first guide layer that is an optical guide layer disposed between first N-type cladding layer 302a and active layer 305, and comprises AlGaInN. In other words, first N-side guide layer 303 is also one example of a first semiconductor layer and is also one example of an N-side semiconductor layer. First N-side guide layer 303 has a higher refractive index and smaller band gap energy than first N-type cladding layer 302a. In addition, first N-side guide layer 303 is an N-type nitride semiconductor layer. In the present embodiment, first N-side guide layer 303 is an N-type Al_{0.159}Ga_{0.791}In_{0.05}N layer that has a thickness of 70 nm, is doped with Si at a concentration of 5×10¹⁷ cm⁻³, and is disposed between third N-type cladding layer 302c and second N-side guide layer 304.

Second N-side guide layer 304 is one example of an N-side semiconductor layer that comprises a nitride semiconductor and is disposed above first N-type cladding layer 302a. In the present embodiment, second N-side guide layer 304 is also one example of a first semiconductor layer that comprises AlGaInN and is disposed between first N-type cladding layer 302a and active layer 305. In the present embodiment, second N-side guide layer 304 is an optical guide layer. The average band gap energy of second N-side guide layer 304 is smaller than the average band gap energy of first N-type cladding layer 302a. Second N-side guide layer 304 is an undoped AlGaInN layer. The average band gap energy, the Al composition ratio, and the In composition ratio of first N-side guide layer 303 are respectively the same as the average band gap energy, the Al composition ratio, and the In composition ratio of second N-side guide layer 304. In the present embodiment, second N-side guide layer 304 is an undoped Al_{0.159}Ga_{0.791}In_{0.05}N layer that has a thickness of 70 nm and is disposed between first N-side guide layer 303 and active layer 305.

Well layer 305b is a nitride semiconductor layer that functions as a well in a quantum well structure and is disposed above barrier layer 105a. In the present embodiment, well layer 305b is an undoped Al_{0.02}Ga_{0.96}In_{0.02}N layer with a thickness of 17.5 nm.

First P-side guide layer 306 is one example of a P-side semiconductor layer that comprises a nitride semiconductor and is disposed above active layer 305. In the present embodiment, first P-side guide layer 306 is also one example of a first semiconductor layer that comprises AlGaInN and is disposed between P-type cladding layer 109 and active layer 305. In the present embodiment, first P-side guide layer 306 is an optical guide layer. The average band gap energy of first P-side guide layer 306 is smaller than the average band gap energy of P-type cladding layer 109. First P-side guide layer 306 is an undoped AlGaInN layer. In the present embodiment, first P-side guide layer 306 is an undoped Al_{0.159}Ga_{0.791}In_{0.05}N layer that has a thickness of 72 nm and is disposed between active layer 305 and electron blocking layer 107. The average band gap energy, the Al composition ratio, and the In composition ratio of second N-side guide layer 304 are respectively the same as the average band gap energy, the Al composition ratio, and the In composition ratio of first P-side guide layer 306. The average band gap energy of first P-side guide layer 306 is same as the average band gap energy of second P-side guide layer 108.

With the nitride semiconductor light-emitting element according to the present embodiment, since first N-side guide layer 303 comprises AlGaInN, tensile strain in the semiconductor stack with respect to substrate 101 can be further reduced.

In the present embodiment, since a part of the N-type cladding layer comprises AlGaInN, tensile strain in the semiconductor stack with respect to substrate 101 can be further reduced. Second N-type cladding layer 302b comprising AlGaInN crystal grows at 850 degrees Celsius. This crystal growth therefore takes longer than, for instance, in the case of semiconductor stack 100S according to Embodiment 1. In the present embodiment, however, since not the whole cladding layer but only second N-type cladding layer 302b that is a part of the cladding layer comprises AlGaInN, an increase in a time required for crystal growth can be suppressed.

In the present embodiment, second N-type cladding layer 302b, first N-side guide layer 303, second N-side guide layer 304, and first P-side guide layer 306, each of which is one example of a first semiconductor layer, have a higher Al composition ratio than first N-type cladding layer 302a and P-type cladding layer 109. It is necessary to increase the band gap energies of barrier layers 105a and 105c to inhibit absorption of light generated in active layer 305, and along with this, it is necessary to increase also the band gap energies of the optical guide layers and the band gap energies of the cladding layers. In the present embodiment, since the Al composition ratio of the first semiconductor layer is higher than the Al composition ratio of first N-type cladding layer 302a and the Al composition ratio of P-type cladding layer 109, the In composition ratio of the first semiconductor layer can be increased. Accordingly, it is possible to reduce tensile strain in the semiconductor stack with respect to substrate 101.

In the present embodiment, second N-type cladding layer 302b, first N-side guide layer 303, second N-side guide layer 304, and first P-side guide layer 306, each of which is one example of a first semiconductor layer, have compressive strain with respect to substrate 101. Stated differently, the lattice constant of AlGaInN included in each of second N-type cladding layer 302b, first N-side guide layer 303, and second N-side guide layer 304, each of which is one example of an N-side semiconductor layer, and the lattice constant of AlGaInN included in first P-side guide layer 306 that is one example of a P-side semiconductor layer is greater than the lattice constant of GaN included in substrate 101. The band gap energy of the first semiconductor layer is larger than the band gap energy of the GaN included in substrate 101. In contrast, the other layers in the semiconductor stack have tensile strain with respect to substrate 101. Accordingly, each of the aforementioned layers having compressive strain can further reduce tensile strain in the semiconductor stack with respect to substrate 101 and inhibit absorption of light generated in active layer 305.

In the present embodiment, the Al composition ratio of each of second N-type cladding layer 302b, first N-side guide layer 303, second N-side guide layer 304, and first P-side guide layer 306, each of which is one example of a first semiconductor layer, is higher than the Al composition ratio of each of barrier layers 105a and 105c. As described above, it is necessary to increase the band gap energies of the guide layers and the band gap energies of the cladding layers to inhibit absorption of light generated in active layer 305. In the present embodiment, since the Al composition ratio of the first semiconductor layer is higher than the Al composition ratio of each of barrier layers 105a and 105c, the In composition ratio of the first semiconductor layer can be increased. Accordingly, tensile strain in the semiconductor stack with respect to substrate 101 can be reduced.

First P-side guide layer 306, which is disposed between electron blocking layer 107 and active layer 305, having compressive strain can form a piezoelectric field from electron blocking layer 107 to active layer 305. This can enhance efficiency of hole injection into active layer 305.

In the present embodiment, the In composition ratio of each of second N-type cladding layer 302b, first N-side guide layer 303, second N-side guide layer 304, and first P-side guide layer 306, each of which is an example of a first semiconductor layer, is higher than the In composition ratio of each of barrier layers 105a and 105c. The Al composition ratio of each of second N-type cladding layer 302b, first N-side guide layer 303, second N-side guide layer 304, and first P-side guide layer 306, each of which is an example of a first semiconductor layer, is lower than or equal to the Al composition ratio of each of barrier layers 105a and 105c. This can reduce tensile strain in the semiconductor stack with respect to substrate 101.

In the present embodiment, since well layer 305b comprising AlGaInN has fluctuation of an In composition ratio in well layer 305b, localization of carriers occurs and light-emission efficiency improves. Since a piezoelectric field can be reduced due to the reduction of the compressive strain compared with when the well layer comprises InGaN, it is possible to increase internal quantum efficiency and reduce the long wavelength shift of an oscillation wavelength.

### Embodiment 4

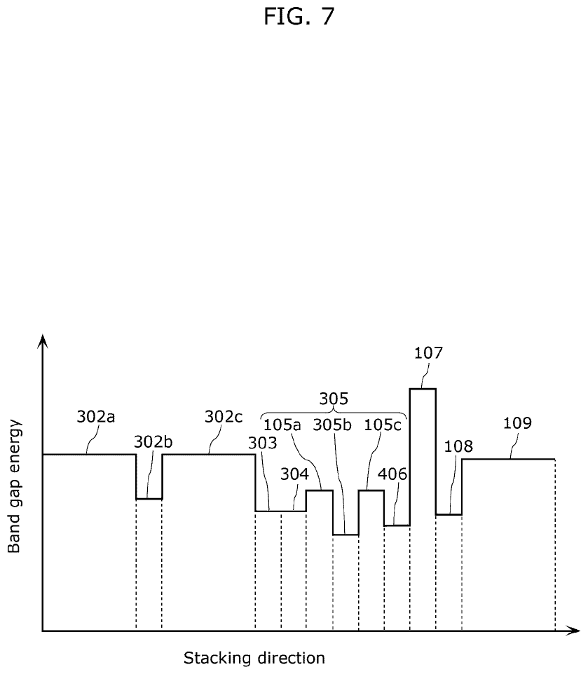

A nitride semiconductor light-emitting element according to Embodiment 4 will be described. The nitride semiconductor light-emitting element according to the present embodiment differs from the nitride semiconductor light-emitting element according to Embodiment 3 in regard to the configuration of a first P-side guide layer. Hereinafter, the nitride semiconductor light-emitting element according to the present embodiment will be described with reference to FIG. 7, focusing on the difference from the nitride semiconductor light-emitting element according to Embodiment 3. FIG. 7 is a graph showing a distribution of the band gap energy of a semiconductor stack according to the present embodiment in the stacking direction of the semiconductor stack.

The nitride semiconductor light-emitting element according to the present embodiment, like the nitride semiconductor light-emitting element according to Embodiment 3, includes substrate 101, the semiconductor stack, current blocking layer 111, P-side electrode 112, and N-side electrode 113. As illustrated in FIG. 7, the semiconductor stack according to the present embodiment includes first N-type cladding layer 302a, second N-type cladding layer 302b, third N-type cladding layer 302c, first N-side guide layer 303, second N-side guide layer 304, active layer 305, first P-side guide layer 406, electron blocking layer 107, second P-side guide layer 108, P-type cladding layer 109, and contact layer 110 (see FIG. 2A).

First P-side guide layer 406 according to the present embodiment is one example of a P-side semiconductor layer that comprises a nitride semiconductor and is disposed above active layer 305. First P-side guide layer 406 is also one example of a first semiconductor layer that comprises AlGaInN and is disposed between P-type cladding layer 109 and active layer 305. In the present embodiment, first P-side guide layer 406 is an undoped Al_{0.18}Ga_{0.76}In_{0.06}N layer that has a thickness of 72 nm and is disposed between active layer 305 and electron blocking layer 107.

In the present embodiment, first P-side guide layer 406 has smaller band gap energy than first N-side guide layer 303 and second N-side guide layer 304, as described above. First P-side guide layer 406 has a higher In composition ratio than first N-side guide layer 303 and second N-side guide layer 304.

With this, compressive strain in first P-side guide layer 406 increases to be greater than compressive strain in first N-side guide layer 303 and second N-side guide layer 304. This results in an increase in a piezoelectric field from electron blocking layer 107 to active layer 305 to be greater than a piezoelectric field from active layer 305 to an N-type cladding layer such as first N-type cladding layer 302a. Accordingly, efficiency of hole injection into active layer 305 can be enhanced. Since holes have a greater effective mass than electrons, the efficiency of the hole injection is likely to decrease compared with efficiency of electron injection. In the present embodiment, increasing compressive strain in first P-side guide layer 406 to be greater than compressive strain in each optical guide layer on the N side can increase a piezoelectric field from electron blocking layer 107 to active layer 305 to be greater than a piezoelectric field from active layer 305 to an N-type cladding layer such as first N-type cladding layer 302a. Accordingly, the efficiency of hole injection, which is more likely to decrease than the efficiency of electron injection, can be enhanced.

### Embodiment 5

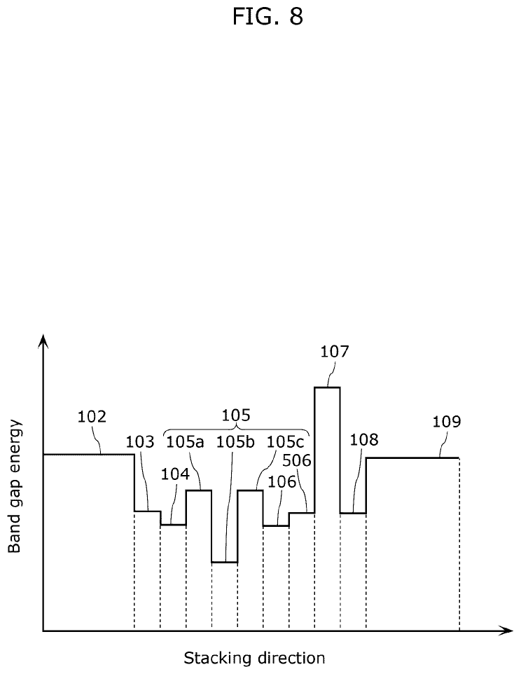

A nitride semiconductor light-emitting element according to Embodiment 5 will be described. The nitride semiconductor light-emitting element according to the present embodiment differs from the nitride semiconductor light-emitting element according to Embodiment 1 in regard to the configuration of a P-side optical guide layer. Hereinafter, the nitride semiconductor light-emitting element according to the present embodiment will be described with reference to FIG. 8, focusing on the difference from nitride semiconductor light-emitting element 100 according to Embodiment 1. FIG. 8 is a graph showing a distribution of the band gap energy of a semiconductor stack according to the present embodiment in the stacking direction of the semiconductor stack.

The nitride semiconductor light-emitting element according to the present embodiment, like the nitride semiconductor light-emitting element according to Embodiment 1, includes substrate 101, the semiconductor stack, current blocking layer 111, P-side electrode 112, and N-side electrode 113. As illustrated in FIG. 8, the semiconductor stack according to the present embodiment includes N-type cladding layer 102, first N-side guide layer 103, second N-side guide layer 104, active layer 105, first P-side guide layer 106, third P-side guide layer 506, electron blocking layer 107, second P-side guide layer 108, P-type cladding layer 109, and contact layer 110 (see FIG. 2A).

The semiconductor stack according to the present embodiment includes third P-side guide layer 506, which is different from semiconductor stack 100S according to Embodiment 1.

Third P-side guide layer 506 is one example of a first guide layer that is an optical guide layer disposed between P-type cladding layer 109 and active layer 105, and comprises a nitride semiconductor. Third P-side guide layer 506 has a higher refractive index and smaller band gap energy than P-type cladding layer 109. The average band gap energy of third P-side guide layer 506 is larger than or equal to the average band gap energy of first P-side guide layer 106. Third P-side guide layer 506 includes Al. Third P-side guide layer 506 is a P-type nitride semiconductor layer. In the present embodiment, third P-side guide layer 506 is a P-type Al_{0.03}Ga_{0.97}N layer that has a thickness of 70 nm, is doped with Mg at a concentration of 1×10¹⁸ cm⁻³, and is disposed between first P-side guide layer 106 and electron blocking layer 107. In the present embodiment, the refractive index and the average band gap energy of third P-side guide layer 506 are respectively the same as the refractive index and the average band gap energy of second P-side guide layer 108.

The nitride semiconductor light-emitting element having such a configuration produces the same advantageous effects as nitride semiconductor light-emitting element 100 according to Embodiment 1.

### Embodiment 6

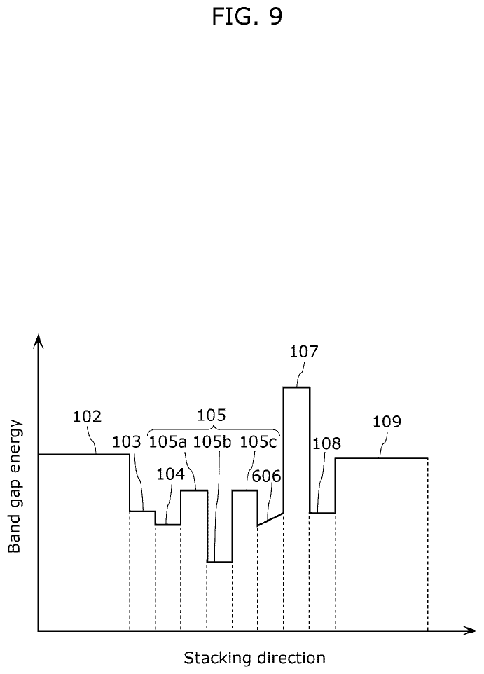

A nitride semiconductor light-emitting element according to Embodiment 6 will be described. The nitride semiconductor light-emitting element according to the present embodiment differs from the semiconductor light-emitting element according to Embodiment 1 in regard to the configuration of a first P-side guide layer. Hereinafter, the nitride semiconductor light-emitting element according to the present embodiment will be described with reference to FIG. 9, focusing on the difference from nitride semiconductor light-emitting element 100 according to Embodiment 1. FIG. 9 is a graph showing a distribution of the band gap energy of a semiconductor stack according to the present embodiment in the stacking direction of the semiconductor stack.

The nitride semiconductor light-emitting element according to the present embodiment, like the nitride semiconductor light-emitting element according to Embodiment 1, includes substrate 101, the semiconductor stack, current blocking layer 111, P-side electrode 112, and N-side electrode 113. As illustrated in FIG. 9, the semiconductor stack according to the present embodiment includes N-type cladding layer 102, first N-side guide layer 103, second N-side guide layer 104, active layer 105, first P-side guide layer 606, electron blocking layer 107, second P-side guide layer 108, P-type cladding layer 109, and contact layer 110 (see FIG. 2A).

The semiconductor stack according to the present embodiment includes an Al composition variation region in which the Al composition ratio of first P-side guide layer 606 monotonically increases with an increase in the distance from active layer 105, which is different from semiconductor stack 100S according to Embodiment 1.

First P-side guide layer 606 according to the present embodiment is one example of a P-side semiconductor layer that comprises a nitride semiconductor and is disposed above active layer 105. In the present embodiment, first P-side guide layer 606 is also one example of a first semiconductor layer that comprises AlGaInN and is disposed between P-type cladding layer 109 and active layer 105. The average band gap energy of first P-side guide layer 606 is smaller than the average band gap energy of P-type cladding layer 109. First P-side guide layer 606 is an undoped AlGaInN layer with a thickness of 72 nm. In the present embodiment, the Al composition ratio of first P-side guide layer 606 is represented by Xpg1. Al composition ratio Xpg1 near an interface of first P-side guide layer 606, which is closer to active layer 105, is 5.0% while Al composition ratio Xpg1 near an interface of first P-side guide layer 606, which is farther from active layer 105, is 5.6%. An In composition ratio in first P-side guide layer 606 is 1.0% and is uniform within the layer. In other words, the composition of first P-side guide layer 606 is Al_{0.05}Ga_{0.94}In_{0.01}N at the interface closer to active layer 105 and is Al_{0.056}Ga_{0.934}In_{0.01}N at the interface farther from active layer 105. First P-side guide layer 606 at the interface closer to active layer 105 has the same band gap energy as second N-side guide layer 104, and first P-side guide layer 606 at the interface farther from active layer 105 has the same band gap energy as second P-side guide layer 108.

The nitride semiconductor light-emitting element having such a configuration produces the same advantageous effects as nitride semiconductor light-emitting element 100 according to Embodiment 1.

In first P-side guide layer 606, by monotonously increasing the Al composition ratio of first P-side guide layer 606 with an increase in the distance from active layer 105, the refractive index of first P-side guide layer 606 can be increased with increasing proximity to active layer 105. Accordingly, since the refractive index of a region close to active layer 105 in first P-side guide layer 606 can be increased, the peak position of a light intensity distribution in the stacking direction can be brought closer to the center of active layer 105 in the stacking direction. This can increase the optical confinement factor of the nitride semiconductor light-emitting element.

In the present embodiment, the whole of first P-side guide layer 606 is an Al composition variation region, but only a part of first P-side guide layer 606 in the stacking direction may be an Al composition variation region.

### Embodiment 7

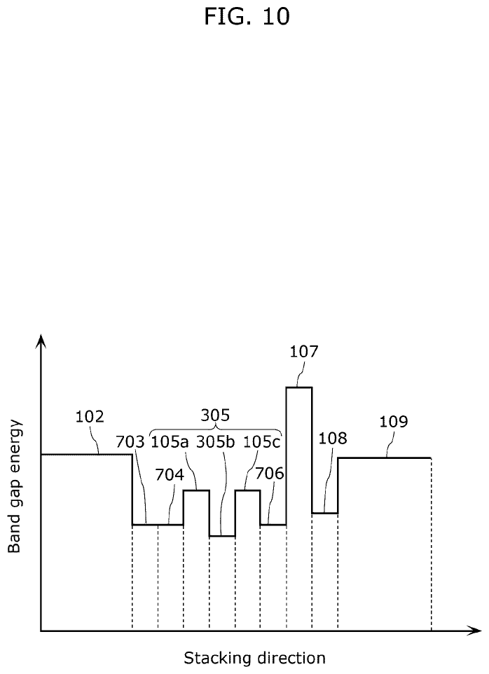

A nitride semiconductor light-emitting element according to Embodiment 7 will be described. The nitride semiconductor light-emitting element according to the present embodiment differs from the nitride semiconductor light-emitting element according to Embodiment 1 in regard to the configurations of a first N-side guide layer, a well layer, and a first P-side guide layer. Hereinafter, the nitride semiconductor light-emitting element according to the present embodiment will be described with reference to FIG. 10, focusing on the difference from nitride semiconductor light-emitting element 100 according to Embodiment 1. FIG. 10 is a graph showing a distribution of the band gap energy of a semiconductor stack according to the present embodiment in the stacking direction of the semiconductor stack.

The nitride semiconductor light-emitting element according to the present embodiment, like the nitride semiconductor light-emitting element according to Embodiment 1, includes substrate 101, the semiconductor stack, current blocking layer 111, P-side electrode 112, and N-side electrode 113. As illustrated in FIG. 10, the semiconductor stack according to the present embodiment includes N-type cladding layer 102, first N-side guide layer 703, second N-side guide layer 104, active layer 305, first P-side guide layer 706, electron blocking layer 107, second P-side guide layer 108, P-type cladding layer 109, and contact layer 110 (see FIG. 2A).

The configuration of active layer 305 according to the present embodiment is the same as the configuration of active layer 305 according to Embodiment 3.

First N-side guide layer 703 according to the present embodiment is one example of a first guide layer that is an optical guide layer disposed between N-type cladding layer 102 and active layer 305, and comprises AlGaInN. In other words, first N-side guide layer 703 is also one example of a first semiconductor layer, and is also one example of an N-side semiconductor layer. First N-side guide layer 703 has a higher refractive index and smaller band gap energy than N-type cladding layer 102. First N-side guide layer 703 is an N-type nitride semiconductor layer. In the present embodiment, first N-side guide layer 703 is an N-type Al_{0.05}Ga_{0.94}In_{0.01}N layer that has a thickness of 70 nm, is doped with Si at a concentration of 5×10¹⁷ cm⁻³, and is disposed between N-type cladding layer 102 and second N-side guide layer 104. The average band gap energy, the Al composition ratio, and the In composition ratio of first N-side guide layer 703 are respectively the same as the average band gap energy, the Al composition ratio, and the In composition ratio of second N-side guide layer 104.

First P-side guide layer 706 is an undoped Al_{0.154}Ga_{0.796}In_{0.05}N layer. The average band gap energy of each of first N-side guide layer 703 and second N-side guide layer 104 is same as the average band gap energy of first P-side guide layer 706. The average band gap energy of each of first N-side guide layer 703, second N-side guide layer 104, and first P-side guide layer 706 is smaller than the average band gap energy of second P-side guide layer 108.

Since the nitride semiconductor light-emitting element according to the present embodiment has the above configuration, layers from barrier layer 105a to first P-side guide layer 706 have compressive strain with respect to substrate 101 and the other layers have tensile strain with respect to substrate 101. Since a piezoelectric field from electron blocking layer 107 to active layer 305 can be formed owing to first P-side guide layer 706 having compressive strain with respect to substrate 101, efficiency of hole injection can be enhanced.

### Embodiment 8

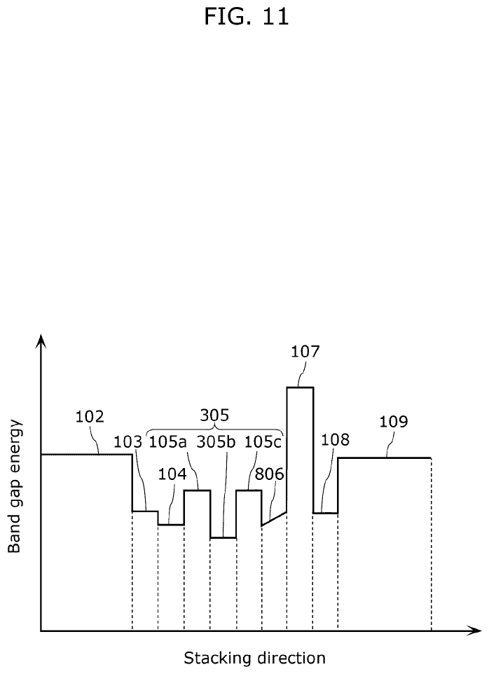

A nitride semiconductor light-emitting element according to Embodiment 8 will be described. The nitride semiconductor light-emitting element according to the present embodiment differs from the nitride semiconductor light-emitting element according to Embodiment 6 in regard to the configurations of a well layer and a first P-side guide layer. Hereinafter, the nitride semiconductor light-emitting element according to the present embodiment will be described with reference to FIG. 11, focusing on the difference from nitride semiconductor light-emitting element 100 according to Embodiment 6. FIG. 11 is a graph showing a distribution of the band gap energy of a semiconductor stack according to the present embodiment in the stacking direction of the semiconductor stack.

The nitride semiconductor light-emitting element according to the present embodiment, like the nitride semiconductor light-emitting element according to Embodiment 6, includes substrate 101, the semiconductor stack, current blocking layer 111, P-side electrode 112, and N-side electrode 113. As illustrated in FIG. 11, the semiconductor stack according to the present embodiment includes N-type cladding layer 102, first N-side guide layer 103, second N-side guide layer 104, active layer 305, first P-side guide layer 806, electron blocking layer 107, second P-side guide layer 108, P-type cladding layer 109, and contact layer 110 (see FIG. 2A).

The configuration of active layer 305 according to the present embodiment is the same as the configuration of active layer 305 according to Embodiment 3.

First P-side guide layer 806 according to the present embodiment is one example of a P-side semiconductor layer that comprises a nitride semiconductor and is disposed above active layer 305. In the present embodiment, first P-side guide layer 806 is also one example of a first semiconductor layer that comprises AlGaInN and is disposed between P-type cladding layer 109 and active layer 305. The average band gap energy of first P-side guide layer 806 is smaller than the average band gap energy of P-type cladding layer 109. First P-side guide layer 806 is an undoped AlGaInN layer with a thickness of 72 nm. In the present embodiment, first P-side guide layer 806 includes a composition variation region in which the composition of first P-side guide layer 806 varies with an increase in the distance from active layer 305. The Al composition ratio of first P-side guide layer 806 is represented by Xpg1 and the In composition ratio of first P-side guide layer 806 is represented by Ypg1. Al composition ratio Xpg1 near an interface of first P-side guide layer 806, which is closer to active layer 305, is 15.4%, and Al composition ratio Xpg1 near an interface of first P-side guide layer 806, which is farther from active layer 305, is 5.6%. In composition ratio Ypg1 near the interface of first P-side guide layer 806, which is closer to active layer 305, is 5.0% and In composition ratio Ypg1 of first P-side guide layer 806, which is farther from active layer 305, is 1.0%. In other words, the composition of first P-side guide layer 806 is Al_{0.154}Ga_{0.796}In_{0.05}N at the interface closer to active layer 305 and is Al_{0.056}Ga_{0.934}In_{0.01}N at the interface farther from active layer 305.

Such first P-side guide layer 806 has compressive strain near the interface with active layer 305 and has tensile strain near the interface with electron blocking layer 107.

In the present embodiment, the whole of first P-side guide layer 806 is a composition variation region, but only a part of first P-side guide layer 806 in the stacking direction may be a composition variation region.

### Embodiment 9

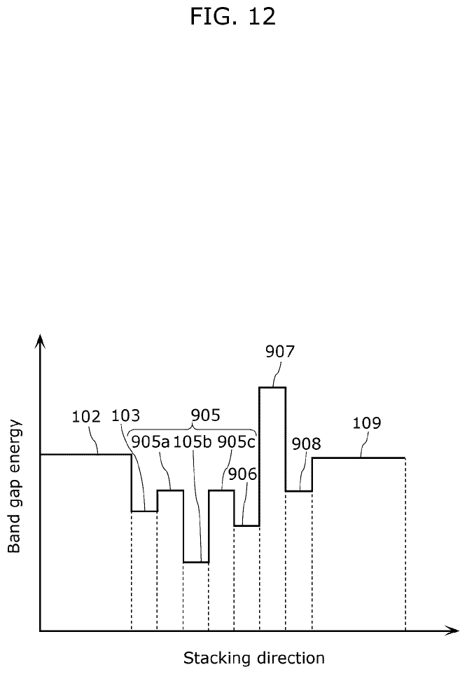

A nitride semiconductor light-emitting element according to Embodiment 9 will be described. The nitride semiconductor light-emitting element according to the present embodiment does not include a second N-side guide layer and has different configurations of a barrier layer, a first P-side guide layer, an electron blocking layer, and a second P-side guide layer, which are different from the nitride semiconductor light-emitting element according to Embodiment 1. Hereinafter, the nitride semiconductor light-emitting element according to the present embodiment will be described with reference to FIG. 12, focusing on the differences from nitride semiconductor light-emitting element 100 according to Embodiment 1. FIG. 12 is a graph showing a distribution of the band gap energy of a semiconductor stack according to the present embodiment in the stacking direction of the semiconductor stack.

The nitride semiconductor light-emitting element according to the present embodiment, like the nitride semiconductor light-emitting element according to Embodiment 1, includes substrate 101, the semiconductor stack, current blocking layer 111, P-side electrode 112, and N-side electrode 113. As illustrated in FIG. 12, the semiconductor stack according to the present embodiment includes N-type cladding layer 102, first N-side guide layer 103, active layer 905, first P-side guide layer 906, electron blocking layer 907, second P-side guide layer 908, P-type cladding layer 109, and contact layer 110 (see FIG. 2A).

First N-side guide layer 103 according to the present embodiment, like first N-side guide layer 103 according to Embodiment 1, is Al_{0.03}Ga_{0.97}N layer, but has a thickness and an impurity concentration different from the thickness and the impurity concentration of first N-side guide layer 103 according to Embodiment 1. First N-side guide layer 103 according to the present embodiment is an undoped Al_{0.03}Ga_{0.97}N layer with a thickness of 140 nm.

Active layer 905 is disposed above and in contact with first N-side guide layer 103. Active layer 905 includes two barrier layers 905a and 905c, and well layer 105b. In the present embodiment, well layer 105b is an undoped Ga_{0.99}In_{0.01}N layer with a thickness of 17.5 nm.

Each of barrier layers 905a and 905c is a nitride semiconductor layer that functions as a barrier in a quantum well structure and is disposed above first N-side guide layer 103. Barrier layer 905c is disposed above barrier layer 905a. In the present embodiment, the band gap energy of each of barrier layers 905a and 905c is larger than the band gap energy of well layer 105b, the average band gap energy of first P-side guide layer 906, and the average band gap energy of first N-side guide layer 103, and is smaller than the average band gap energy of electron blocking layer 907. Each of barrier layers 905a and 905c is an undoped Al_{0.04}Ga_{0.96}N layer with a thickness of 10 nm.

First P-side guide layer 906 is one example of a P-side semiconductor layer that comprises a nitride semiconductor and is disposed above active layer 905. In the present embodiment, first P-side guide layer 906 is also one example of a first semiconductor layer that comprises AlGaInN and is disposed between P-type cladding layer 109 and active layer 905. In other words, out of first N-side guide layer 103 (i.e., an N-side semiconductor layer) and first P-side guide layer 906 (i.e., a P-side semiconductor layer) in nitride semiconductor light-emitting element 100, only first P-side guide layer 906 comprises AlGaInN. In the present embodiment, first P-side guide layer 906 is an optical guide layer. The average band gap energy of first P-side guide layer 906 is smaller than the average band gap energy of P-type cladding layer 109. First P-side guide layer 906 is an undoped AlGaInN layer. In the present embodiment, first P-side guide layer 906 is an undoped Al_{0.04}Ga_{0.9516}In_{0.0084}N layer with a thickness of 72 nm.

Electron blocking layer 907 is a nitride semiconductor layer disposed between first P-side guide layer 906 and P-type cladding layer 109. The band gap energy of electron blocking layer 907 is larger than the band gap energy of barrier layer 905c. This can inhibit leakage of electrons from active layer 905 to P-type cladding layer 109. In the present embodiment, the band gap energy of electron blocking layer 907 is larger than the band gap energy of P-type cladding layer 109. Electron blocking layer 907 is a P-type Al_{0.36}Ga_{0.64}N layer that has a thickness of 5 nm and is doped with Mg at a concentration of 1×10¹⁹ cm³.

Second P-side guide layer 908 is one example of a first guide layer that is an optical guide layer disposed between P-type cladding layer 109 and active layer 905, and comprises a nitride semiconductor. Second P-side guide layer 908 is also one example of a second guide layer disposed between electron blocking layer 907 and P-type cladding layer 109. Second P-side guide layer 908 has a higher refractive index and smaller band gap energy than P-type cladding layer 109. The average band gap energy of second P-side guide layer 908 is larger than or equal to the average band gap energy of first P-side guide layer 906. Second P-side guide layer 908 includes Al. Second P-side guide layer 908 is a P-type nitride semiconductor layer. In the present embodiment, second P-side guide layer 908 is a P-type Al_{0.04}Ga_{0.96}N layer that has a thickness of 148 nm, is doped with Mg at a concentration of 1×10¹⁸ cm⁻³, and is disposed between electron blocking layer 907 and P-type cladding layer 109. The average band gap energy of second P-side guide layer 908 is same as the average band gap energy of each of barrier layers 905a and 905c.

As is the case of the present embodiment, the nitride semiconductor light-emitting element in which only first P-side guide layer 906, out of first N-side guide layer 103 and first P-side guide layer 906, comprises AlGaInN can reduce tensile strain in the semiconductor stack with respect to substrate 101. Out of first N-side guide layer 103 and first P-side guide layer 906, only first N-side guide layer 103 may comprise AlGaInN. The nitride semiconductor light-emitting element having such a configuration can also reduce tensile strain in the semiconductor stack with respect to substrate 101 since first P-side guide layer 906 comprises AlGaInN.

As is the case of the present embodiment, barrier layers 905a and 905c may comprise AlGaN. A nitride semiconductor light-emitting element having such a configuration can reduce tensile strain in the semiconductor stack with respect to substrate 101 since first P-side guide layer 906 comprises AlGaInN.

In the present embodiment, first P-side guide layer 906 comprises AlGaInN and first N-side guide layer 103 comprises AlGaN. Thus, the In composition ratio of first P-side guide layer 906 is higher than the In composition ratio of first N-side guide layer 103. This can reduce the average band gap energy of first P-side guide layer 906 to be smaller than the average band gap energy of first N-side guide layer 103. In the present embodiment, tensile strain in first P-side guide layer 906 with respect to substrate 101 is less than tensile strain in first N-side guide layer 103 with respect to substrate 101. Accordingly, a piezoelectric field from active layer 905 to electron blocking layer 907 is smaller than a piezoelectric field from N-type cladding layer 102 to active layer 905. For this reason, the efficiency of hole injection, which is more likely to decrease than the efficiency of electron injection, can be enhanced, as is the case of Embodiment 4.

### Embodiment 10

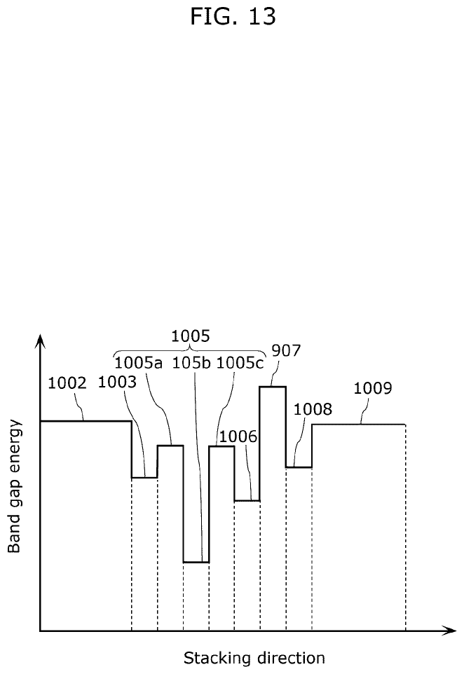

A nitride semiconductor light-emitting element according to Embodiment 10 will be described. The semiconductor stack of the nitride semiconductor light-emitting element according to the present embodiment differs from the semiconductor stack according to Embodiment 9 in regard to the configurations of components other than the well layer, the electron blocking layer, and the contact layer. The Al composition ratio of, for instance, a cladding layer of the nitride semiconductor light-emitting element according to the present embodiment is higher than the Al composition ratio of a cladding layer of the nitride semiconductor light-emitting element according to Embodiment 9. Hereinafter, the nitride semiconductor light-emitting element according to the present embodiment will be described with reference to FIG. 13, focusing on the difference from the nitride semiconductor light-emitting element according to Embodiment 9. FIG. 13 is a graph showing a distribution of the band gap energy of the semiconductor stack according to the present embodiment in the stacking direction of the semiconductor stack.

The nitride semiconductor light-emitting element according to the present embodiment, like the nitride semiconductor light-emitting element according to Embodiment 9, includes substrate 101, the semiconductor stack, current blocking layer 111, P-side electrode 112, and N-side electrode 113. As illustrated in FIG. 13, the semiconductor stack according to the present embodiment includes N-type cladding layer 1002, first N-side guide layer 1003, active layer 1005, first P-side guide layer 1006, electron blocking layer 907, second P-side guide layer 1008, P-type cladding layer 1009, and contact layer 110 (see FIG. 2A).

N-type cladding layer 1002 is one example of a first cladding layer that comprises AlGaN and is disposed above substrate 101. The conductivity type of N-type cladding layer 1002 is N type. N-type cladding layer 1002 has a lower refractive index and larger average band gap energy than active layer 1005. In the present embodiment, N-type cladding layer 1002 is an N-type Al_{0.10}Ga_{0.90}N layer that has a thickness of 800 nm and is doped with Si at a concentration of 5×10¹⁷ cm⁻³.

First N-side guide layer 1003 is one example of a first guide layer that is an optical guide layer disposed between N-type cladding layer 1002 and active layer 1005, and comprises a nitride semiconductor. First N-side guide layer 1003 has a higher refractive index and smaller band gap energy than N-type cladding layer 1002. First N-side guide layer 1003 includes Al. First N-side guide layer 1003 is an undoped nitride semiconductor layer. In the present embodiment, first N-side guide layer 1003 is an undoped Al_{0.05}Ga_{0.95}N layer that has a thickness of 70 nm and is disposed between N-type cladding layer 1002 and active layer 1005.

Active layer 1005 includes well layer 105b and two barrier layers 1005a and 1005c.

Each of barrier layers 1005a and 1005c is a nitride semiconductor layer that functions as a barrier in a quantum well structure and is disposed above first N-side guide layer 1003. Barrier layer 1005c is disposed above barrier layer 1005a. In the present embodiment, the band gap energy of each of barrier layers 1005a and 1005c is larger than the band gap energy of well layer 105b, the average band gap energy of first P-side guide layer 1006 and the average band gap energy of first N-side guide layer 1003, and is smaller than the average band gap energy of electron blocking layer 907. Each of barrier layers 1005a and 1005c is an undoped Al_{0.07}Ga_{0.93}N layer with a thickness of 10 nm.

First P-side guide layer 1006 is one example of a P-side semiconductor layer that comprises a nitride semiconductor and is disposed above active layer 1005. In the present embodiment, first P-side guide layer 1006 is also one example of a first semiconductor layer that comprises AlGaInN and is disposed between P-type cladding layer 1009 and active layer 1005. In the present embodiment, first P-side guide layer 1006 is an optical guide layer. The average band gap energy of first P-side guide layer 1006 is smaller than the average band gap energy of P-type cladding layer 1009. First P-side guide layer 1006 is an undoped AlGaInN layer. In the present embodiment, first P-side guide layer 1006 is an undoped Al_{0.07}Ga_{0.917}In_{0.013}N layer with a thickness of 72 nm.

Second P-side guide layer 1008 is one example of a first guide layer that is an optical guide layer disposed between P-type cladding layer 1009 and active layer 1005, and comprises a nitride semiconductor. Second P-side guide layer 1008 is also one example of a second guide layer disposed between electron blocking layer 907 and P-type cladding layer 1009. Second P-side guide layer 1008 has a higher refractive index and smaller band gap energy than P-type cladding layer 1009. The average band gap energy of second P-side guide layer 1008 is larger than or equal to the average band gap energy of first P-side guide layer 1006. Second P-side guide layer 1008 includes Al. Second P-side guide layer 1008 is a P-type nitride semiconductor layer. In the present embodiment, second P-side guide layer 1008 is a doped P-type Al_{0.06}Ga_{0.94}N layer that has a thickness of 148 nm, is doped with Mg at a concentration of 1×10¹⁸ cm⁻³, and is disposed between electron blocking layer 907 and P-type cladding layer 1009.

P-type cladding layer 1009 is one example of a first cladding layer that comprises AlGaN and is disposed above substrate 101. The conductivity type of P-type cladding layer 1009 is P type. In the present embodiment, P-type cladding layer 1009 is disposed above first P-side guide layer 1006. P-type cladding layer 1009 has a lower refractive index and larger average band gap energy than active layer 1005. The average band gap energy of P-type cladding layer 1009 is smaller than the average band gap energy of electron blocking layer 907. In the present embodiment, P-type cladding layer 1009 is doped with Mg as an impurity. The impurity concentration of P-type cladding layer 1009 is lower in an end portion close to active layer 1005 than in an end portion far from active layer 1005. Specifically, P-type cladding layer 1009 is an AlGaN layer with a thickness of 450 nm and includes: a P-type Al_{0.10}Ga_{0.90}N layer that has a thickness of 150 nm, is doped with Mg at a concentration of 2×10¹⁸ cm⁻³, and is disposed on a side close to active layer 1005; and a P-type Al_{0.10}Ga_{0.90}N layer that has a thickness of 300 nm, is doped with Mg at a concentration of 1×10¹⁹ cm⁻³, and is disposed on a side far from active layer 1005.

Like the semiconductor stack according to the present embodiment, even when the Al composition ratio of, for instance, each cladding layer is large, tensile strain in the semiconductor stack with respect to substrate 101 can be reduced owing to the semiconductor stack including first P-side guide layer 1006 that comprises AlGaInN.

### Embodiment 11

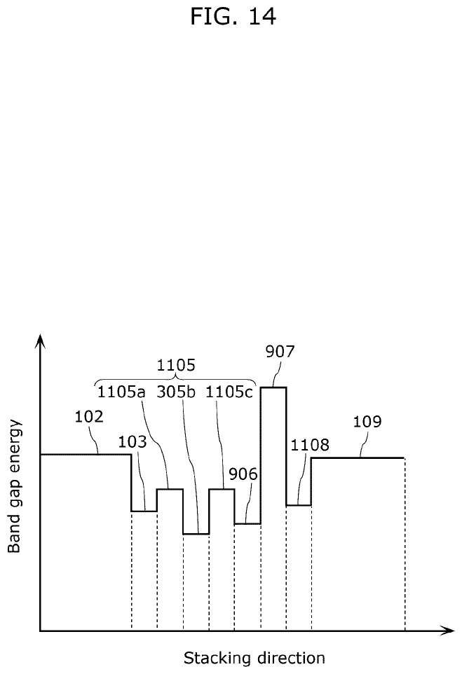

A nitride semiconductor light-emitting element according to Embodiment 11 will be described. The semiconductor stack of the nitride semiconductor light-emitting element according to the present embodiment differs from the semiconductor stack according to Embodiment 9 in regard to the configuration of an active layer. In the nitride semiconductor light-emitting element according to the present embodiment, each layer in the active layer comprises AlGaInN. Hereinafter, the nitride semiconductor light-emitting element according to the present embodiment will be described with reference to FIG. 14, focusing on the difference from the nitride semiconductor light-emitting element according to Embodiment 9. FIG. 14 is a graph showing a distribution of the band gap energy of the semiconductor stack according to the present embodiment in the stacking direction of the semiconductor stack.

The nitride semiconductor light-emitting element according to the present embodiment, like the nitride semiconductor light-emitting element according to Embodiment 9, includes substrate 101, the semiconductor stack, current blocking layer 111, P-side electrode 112, and N-side electrode 113. As illustrated in FIG. 14, the semiconductor stack according to the present embodiment includes N-type cladding layer 102, first N-side guide layer 103, active layer 1105, first P-side guide layer 906, electron blocking layer 907, second P-side guide layer 908, P-type cladding layer 109, and contact layer 110 (see FIG. 2A).

Active layer 1105 includes well layer 305b and two barrier layers 1105a and 1105c. In the present embodiment, well layer 305b is an undoped Al_{0.02}Ga_{0.96} In_{0.02}N layer with a thickness of 17.5 nm.

Each of barrier layers 1105a and 1105c is a nitride semiconductor layer that functions as a barrier in a quantum well structure and is disposed above first N-side guide layer 103. Barrier layer 1105c is disposed above barrier layer 1105a. In the present embodiment, the band gap energy of each of barrier layers 1105a and 1105c is larger than the band gap energy of well layer 305b, the average band gap energy of first P-side guide layer 906, and the average band gap energy of first N-side guide layer 103, and is smaller than the average band gap energy of electron blocking layer 907. Each of barrier layers 1105a and 1105c is an undoped Al_{0.07}Ga_{0.92}In_{0.02}N layer with a thickness of 10 nm.

The nitride semiconductor light-emitting element according to the present embodiment produces the same advantageous effects as the nitride semiconductor light-emitting element according to Embodiment 9. In addition, like the semiconductor stack according to the present embodiment, the Al composition ratio of first P-side guide layer 906 that is one example of a first semiconductor layer can be reduced to be lower than the Al composition ratio of each of barrier layers 1105a and 1105c owing to each layer in active layer 1105 comprising AlGaInN. This can further reduce tensile strain in the semiconductor stack with respect to substrate 101.

### Embodiment 12

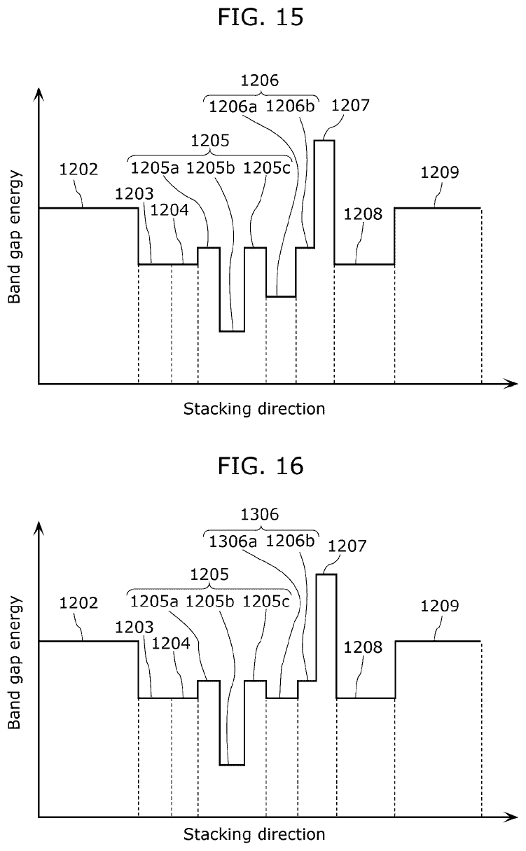

A nitride semiconductor light-emitting element according to Embodiment 12 will be described. The semiconductor stack of the nitride semiconductor light-emitting element according to the present embodiment differs from the semiconductor stack according to Embodiment 1 mainly in regard to the configurations of an active layer and a first P-side guide layer. Hereinafter, the nitride semiconductor light-emitting element according to the present embodiment will be described with reference to FIG. 15, focusing on the difference from the nitride semiconductor light-emitting element according to Embodiment 1. FIG. 15 is a graph showing a distribution of the band gap energy of the semiconductor stack according to the present embodiment in the stacking direction of the semiconductor stack.

The nitride semiconductor light-emitting element according to the present embodiment, like the nitride semiconductor light-emitting element according to Embodiment 1, includes substrate 101, the semiconductor stack, current blocking layer 111, P-side electrode 112, and N-side electrode 113. As illustrated in FIG. 15, the semiconductor stack according to the present embodiment includes N-type cladding layer 1202, first N-side guide layer 1203, second N-side guide layer 1204, active layer 1205, first P-side guide layer 1206, electron blocking layer 1207, second P-side guide layer 1208, P-type cladding layer 1209, and contact layer 110 (see FIG. 2A).

N-type cladding layer 1202 is one example of a first cladding layer that comprises AlGaN and is disposed above substrate 101. The conductivity type of N-type cladding layer 1202 is N type. N-type cladding layer 1202 has a lower refractive index and larger average band gap energy than active layer 1205. In the present embodiment, N-type cladding layer 1202 is an N-type Al_{0.065}Ga_{0.935}N layer that has a thickness of 900 nm and is doped with Si at a concentration of 1×10¹⁸ cm⁻³.

First N-side guide layer 1203 is one example of a first guide layer that is an optical guide layer disposed between N-type cladding layer 1202 and active layer 1205, and comprises a nitride semiconductor. First N-side guide layer 1203 has a higher refractive index and smaller band gap energy than N-type cladding layer 1202. First N-side guide layer 1203 includes Al. In the present embodiment, first N-side guide layer 1203 is an N-type Al_{0.03}Ga_{0.97}N layer that has a thickness of 127 nm, is doped with Si at a concentration of 1×10¹⁸ cm⁻³, and is disposed between N-type cladding layer 1202 and second N-side guide layer 1204.

Second N-side guide layer 1204 is one example of an N-side semiconductor layer that comprises a nitride semiconductor and is disposed above N-type cladding layer 1202. In the present embodiment, second N-side guide layer 1204 is a semiconductor layer that comprises AlGaN and is disposed between N-type cladding layer 1202 and active layer 1205. In the present embodiment, second N-side guide layer 1204 is an optical guide layer. The average band gap energy of second N-side guide layer 1204 is smaller than the average band gap energy of N-type cladding layer 1202. Second N-side guide layer 1204 is an undoped AlGaN layer. The average band gap energy and the Al composition ratio of first N-side guide layer 1203 are respectively the same as the average band gap energy and the Al composition ratio of second N-side guide layer 1204. In the present embodiment, second N-side guide layer 1204 is an undoped Al_{0.03}Ga_{0.97}N layer that has a thickness of 80 nm and is disposed between first N-side guide layer 1203 and active layer 1205.

Active layer 1205 includes well layer 1205b and two barrier layers 1205a and 1205c. In the present embodiment, the configuration of well layer 1205b is determined so that the peak wavelength of photoluminescence from the nitride semiconductor light-emitting element is 366 nm. Well layer 1205b is an undoped Ga_{0.99}In_{0.01}N layer with a thickness of 17.5 nm.

Barrier layer 1205a is a nitride semiconductor layer that functions as a barrier in a quantum well structure and is disposed between first N-side guide layer 1203 and well layer 1205b. Barrier layer 1205c is a nitride semiconductor layer that functions as a barrier in the quantum well structure and is disposed between well layer 1205b and first P-side guide layer 1206. In the present embodiment, the band gap energy of each of barrier layers 1205a and 1205c is larger than the band gap energy of well layer 1205b, the average band gap energy of first P-side guide layer 1206, and the average band gap energy of first N-side guide layer 1203, and is smaller than the average band gap energy of electron blocking layer 1207. Barrier layer 1205a is an undoped Al_{0.04}Ga_{0.96}N layer with a thickness of 14 nm, and barrier layer 1205c is an undoped Al_{0.04}Ga_{0.96}N layer with a thickness of 12 nm.

First P-side guide layer 1206 is one example of a P-side semiconductor layer that comprises a nitride semiconductor and is disposed above active layer 1205. In the present embodiment, first P-side guide layer 1206 includes lower first P-side guide layer 1206a and upper first P-side guide layer 1206b. Lower first P-side guide layer 1206a comprises AlGaInN and is disposed between P-type cladding layer 1209 and active layer 1205. Upper first P-side guide layer 1206b comprises AlGaN and is disposed between lower first P-side guide layer 1206a and P-type cladding layer 1209. Lower first P-side guide layer 1206a is one example of a first semiconductor layer disposed between active layer 1205 and P-type cladding layer 1209 comprising AlGaN. Lower first P-side guide layer 1206a is also one example of a P-side semiconductor layer that comprises a nitride semiconductor and is disposed above active layer 1205. In the present embodiment, first P-side guide layer 1206 is an optical guide layer. The average band gap energy of each of lower first P-side guide layer 1206a and upper first P-side guide layer 1206b is smaller than the average band gap energy of P-type cladding layer 1209. In the present embodiment, first P-side guide layer 1206 includes: lower first P-side guide layer 1206a that is an undoped Al_{0.04}Ga_{0.95}In_{0.01}N layer that has a thickness of 53 nm and is disposed between active layer 1205 and electron blocking layer 1207; and upper first P-side guide layer 1206b that is an undoped Al_{0.04}Ga_{0.96}N layer with a thickness of 7 nm. Lower first P-side guide layer 1206a has compressive strain with respect to substrate 101. In upper first P-side guide layer 1206b, an Mg concentration may increase with increasing proximity to an interface with electron blocking layer 1207 in a region including the interface. The impurity concentration of upper first P-side guide layer 1206b may not be uniform. Upper first P-side guide layer 1206b has a lower refractive index and larger band gap energy than lower first P-side guide layer 1206a.

Electron blocking layer 1207 is a nitride semiconductor layer disposed between first P-side guide layer 1206 and P-type cladding layer 1209. The band gap energy of electron blocking layer 1207 is larger than the band gap energy of barrier layer 1205c. This can inhibit leakage of electrons from active layer 1205 to P-type cladding layer 1209. In the present embodiment, the band gap energy of electron blocking layer 1207 is larger than the band gap energy of P-type cladding layer 1209. Electron blocking layer 1207 is a P-type Al_{0.36}Ga_{0.64}N layer that has a thickness of 1.6 nm and is doped with Mg at a concentration of 1.5×10¹⁹ cm⁻³.

Second P-side guide layer 1208 is one example of a first guide layer that is an optical guide layer disposed between P-type cladding layer 1209 and active layer 1205, and comprises a nitride semiconductor. Second P-side guide layer 1208 is also one example of a second guide layer disposed between electron blocking layer 1207 and P-type cladding layer 1209. Second P-side guide layer 1208 has a higher refractive index and smaller band gap energy than P-type cladding layer 1209. Second P-side guide layer 1208 has a higher refractive index and smaller band gap energy than lower first P-side guide layer 1206a. Second P-side guide layer 1208 has the same refractive index and the same average band gap energy as second N-side guide layer 1204. Second P-side guide layer 1208 includes Al. Second P-side guide layer 1208 is a P-type nitride semiconductor layer. In the present embodiment, second P-side guide layer 1208 is a P-type Al_{0.03}Ga_{0.97}N layer that has a thickness of 110 nm, is doped with Mg at a concentration of 2×10¹⁸ cm⁻³, and is disposed between electron blocking layer 1207 and P-type cladding layer 1209.

P-type cladding layer 1209 is one example of a first cladding layer that comprises AlGaN and is disposed above substrate 101. The conductivity type of P-type cladding layer 1209 is P type. In the present embodiment, P-type cladding layer 1209 is disposed above first P-side guide layer 1206. P-type cladding layer 1209 has a lower refractive index and larger average band gap energy than active layer 1205. The average band gap energy of P-type cladding layer 1209 is smaller than the average band gap energy of electron blocking layer 1207. In the present embodiment, P-type cladding layer 1209 is doped with Mg as an impurity. The impurity concentration of P-type cladding layer 1209 is lower in an end portion close to active layer 1205 than in an end portion far from active layer 1205. Specifically, P-type cladding layer 1209 is an AlGaN layer with a thickness of 450 nm and includes: a P-type Al_{0.065}Ga_{0.935}N layer that has a thickness of 150 nm, is doped with Mg at a concentration of 2×10¹⁸ cm⁻³, and is disposed on a side close to active layer 1205; and a P-type Al_{0.065}Ga_{0.935}N layer that has a thickness of 300 nm, is doped with Mg at a concentration of 1×10¹⁹ cm⁻³, and is disposed on a side far from active layer 1205.

The nitride semiconductor light-emitting element according to the present embodiment can reduce tensile strain in the semiconductor stack with respect to substrate 101. In the nitride semiconductor light-emitting element according to the present embodiment, an optical confinement factor for confining light to active layer 1205 is 5.2%, light loss (i.e., waveguide loss) is 3.8 cm⁻¹, and an effective refractive index difference is 14.0×10⁻³. An effective refractive index difference as used herein refers to the difference between the average refractive index of a region below the ridge (see 109R in FIG. 2A) formed in P-type cladding layer 1209 and light is present and the average refractive index of a region other than the region below the ridge and light is present.

In the nitride semiconductor light-emitting element according to the present embodiment, the peak position of a light intensity distribution in the stacking direction of the semiconductor stack can be positioned at a position that is 11.3 nm above the interface between second N-side guide layer 1204 and barrier layer 1205a. In the present embodiment, the peak position of the light intensity distribution in the stacking direction can be brought closer to well layer 1205b in active layer 1205.

In the nitride semiconductor light-emitting element according to the present embodiment, a divergence angle of emitted light in the stacking direction is 44.7 degrees. A divergence angle used herein is a parameter indicating an angle of divergence of emitted light, and is determined so that a light intensity at a divergence angle is 1/e² of a light intensity on an optical axis.

The band gap energy of lower first P-side guide layer 1206a that comprises AlGaInN needs to be larger than the band gap energy of GaN and smaller than or equal to the band gap energy of second P-side guide layer 1208. By thus defining the band gap energy of lower first P-side guide layer 1206a, it is possible to increase the refractive index of lower first P-side guide layer 1206a to be higher than or equal to the refractive index of second P-side guide layer 1208 while reducing the waveguide loss due to absorption of light of a laser oscillation wavelength. In this case, the controllability of positioning the highest position of the peak intensity of a light distribution in the vertical direction toward a position in the vicinity of the well layer can be enhanced, and low waveguide loss can be obtained while increasing the optical confinement factor of the nitride semiconductor light-emitting element.

In the present embodiment, a nitride semiconductor light-emitting element having excellent properties can be achieved, as described above.

The configuration of the nitride semiconductor light-emitting element according to the present embodiment is not limited to the configuration example described above. For example, the composition of lower first P-side guide layer 1206a in first P-side guide layer 1206 may be different from the above-described configuration example. The following describes Variation 1 in which lower first P-side guide layer 1206a is different from the above-described configuration example.

In Variation 1, lower first P-side guide layer 1206a is an undoped Al_{0.04}Ga_{0.945}In_{0.015}N layer with a thickness of 53 nm. Lower first P-side guide layer 1206a has compressive strain with respect to substrate 101.

A nitride semiconductor light-emitting element according to Variation 1 produces the same advantageous effects as the nitride semiconductor light-emitting element according to the present embodiment described above. In the nitride semiconductor light-emitting element according to Variation 1, an optical confinement factor for confining light to active layer 1205 is 4.8%, light loss is 4.3 cm⁻¹, and an effective refractive index difference is 12.9×10⁻³.

The nitride semiconductor light-emitting element according to Variation 1 can position the peak position of a light intensity distribution in the stacking direction to a position that is 3.5 nm above the interface between second N-side guide layer 1204 and barrier layer 1205a. Thus, in Variation 1, the peak position of the light intensity distribution in the stacking direction can be positioned near well layer 1205b in active layer 1205. In the nitride semiconductor light-emitting element according to Variation 1, the divergence angle of emitted light in the stacking direction is 42.5 degrees.

The configuration of lower first P-side guide layer 1206a is not limited to the example above. For example, not only the In composition ratio but also the thickness of lower first P-side guide layer 1206a may be different from the In composition ratio and the thickness of lower first P-side guide layer 1206a according to the present embodiment. For example, lower first P-side guide layer 1206a according to Variation 2 may be an undoped Al_{0.04}Ga_{0.945}In_{0.015}N layer with a thickness of 25 nm. In such a nitride semiconductor light-emitting element according to Variation 2, an optical confinement factor for confining light to active layer 1205 is 4.8%, light loss is 4.7 cm⁻¹, and an effective refractive index difference is 13.9×10⁻³. In the nitride semiconductor light-emitting element according to Variation 2, the peak position of a light intensity distribution in the stacking direction can be positioned to a position that is 2.3 nm above the interface between second N-side guide layer 1204 and barrier layer 1205a. Thus, in the nitride semiconductor light-emitting element according to Variation 2, the peak position of the light intensity distribution in the stacking direction can be positioned near well layer 1205b in active layer 1205. In the nitride semiconductor light-emitting element according to Variation 2, the divergence angle of emitted light in the stacking direction is 42.4 degrees.

As described above, the present embodiment and the variations thereof can achieve a nitride semiconductor light-emitting element having excellent properties.

### Embodiment 13

A nitride semiconductor light-emitting element according to Embodiment 13 will be described. The semiconductor stack of the nitride semiconductor light-emitting element according to the present embodiment differs from the semiconductor stack according to Embodiment 12 mainly in regard to the configuration of a first P-side guide layer. Hereinafter, the nitride semiconductor light-emitting element according to the present embodiment will be described with reference to FIG. 16, focusing on the difference from the nitride semiconductor light-emitting element according to Embodiment 12. FIG. 16 is a graph showing a distribution of the band gap energy of the semiconductor stack according to the present embodiment in the stacking direction of the semiconductor stack.

The nitride semiconductor light-emitting element according to the present embodiment, like the nitride semiconductor light-emitting element according to Embodiment 1, includes substrate 101, the semiconductor stack, current blocking layer 111, P-side electrode 112, and N-side electrode 113. As illustrated in FIG. 15, the semiconductor stack according to the present embodiment includes N-type cladding layer 1202, first N-side guide layer 1203, second N-side guide layer 1204, active layer 1205, first P-side guide layer 1306, electron blocking layer 1207, second P-side guide layer 1208, P-type cladding layer 1209, and contact layer 110 (see FIG. 2A).

First P-side guide layer 1306 according to the present embodiment is one example of a P-side semiconductor layer that comprises a nitride semiconductor and is disposed above active layer 1205. In the present embodiment, first P-side guide layer 1306 includes lower first P-side guide layer 1306a and upper first P-side guide layer 1206b. Lower first P-side guide layer 1306a comprises AlGaInN and is disposed between P-type cladding layer 1209 and active layer 1205. Upper first P-side guide layer 1206b comprises AlGaN and is disposed between lower first P-side guide layer 1306a and P-type cladding layer 1209. Lower first P-side guide layer 1306a is one example of a first semiconductor layer disposed between active layer 1205 and P-type cladding layer 1209 comprising AlGaN. Lower first P-side guide layer 1306a is also one example of a P-side semiconductor layer that comprises a nitride semiconductor and is disposed above active layer 1205. First P-side guide layer 1306 according to the present embodiment is different from first P-side guide layer 1206 according to Embodiment 12 in regard to the In composition ratio of lower first P-side guide layer 1306a. In the present embodiment, first P-side guide layer 1306 includes the following layers disposed between active layer 1205 and electron blocking layer 1207: lower first P-side guide layer 1306a that is an undoped Al_{0.04}Ga_{0.955}In_{0.005}N layer with a thickness of 53 nm; and upper first P-side guide layer 1206b that is an undoped Al_{0.04}Ga_{0.96}N layer with a thickness of 7 nm. Lower first P-side guide layer 1306a has tensile strain with respect to substrate 101. Lower first P-side guide layer 1306a and second P-side guide layer 1208 have a substantially same refractive index and the same band gap energy.

Like the nitride semiconductor light-emitting element according to Embodiment 12, the nitride semiconductor light-emitting element according to the present embodiment having the above configuration can achieve a nitride semiconductor light-emitting element having excellent properties.

### Variations, etc.

Although the nitride semiconductor light-emitting element according to the present disclosure has been described above based on each of the embodiments, the present disclosure is not limited to each of the embodiments.

For example, each of the embodiments gives an example in which the nitride semiconductor light-emitting element is a semiconductor laser element, but the nitride semiconductor light-emitting element is not limited to a semiconductor laser element. The nitride semiconductor light-emitting element may be, for example, a superluminescent diode. In this case, the reflectance of the end face of the semiconductor stack included in the nitride semiconductor light-emitting element with respect to light emitted from the semiconductor stack may be 0.1% or less. Such a reflectance can be achieved by, for example, forming, on the end face, an anti-reflective film including, for instance, a dielectric multilayer film. Alternatively, if the semiconductor stack has an inclined stripe structure in which the ridge serving as a waveguide is inclined at an angle of 5 degrees or more from the normal direction of the front end face of the semiconductor stack and intersects the front end face, the percentage of the component of guided light that is reflected at the front end face and couples with the waveguide to become guided light again can be reduced to a small value of 0.1% or less.

In each of the embodiments, the P-type cladding layer is a layer whose Al composition ratio is uniform, but the configuration of the P-type cladding layer is not limited to this example. For example, the P-type cladding layer may have a superlattice structure in which each of AlGaN layers and each of GaN layers are alternately stacked.

In each of the embodiments, the semiconductor stack includes a second P-side guide layer, but may not include a second P-side guide layer.

In addition, the nitride semiconductor light-emitting element according to each of the embodiments includes both a first N-side guide layer and a first P-side guide layer, but may include a first N-side guide layer and may not include a first P-side guide layer, or may include a first P-side guide layer and may not include a first N-side guide layer.

In each of the embodiments, the N-type cladding layer is stacked on substrate 101, but other layer may be interposed between substrate 101 and the N-type cladding layer. For example, a buffer layer or an underlying layer may be interposed between substrate 101 and the N-type cladding layer.

Various modifications of the above embodiments that may be conceived by those skilled in the art, as well as embodiments resulting from arbitrary combinations of elements and functions from different embodiments that do not depart from the essence of the present disclosure are also included in the present disclosure.

### INDUSTRIAL APPLICABILITY

The nitride semiconductor light-emitting element according to the present disclosure can be applied to, for example, a light source for light exposure devices and processing machines, as a high-output, high-efficiency light source.

1. A nitride semiconductor light-emitting element comprising:
a substrate comprising GaN;
an N-type cladding layer comprising AlGaN and disposed above the substrate;
an active layer disposed above the N-type cladding layer;
a P-side semiconductor layer comprising a nitride semiconductor and disposed above the active layer;
a P-type cladding layer comprising AlGaN and disposed above the P-side semiconductor layer; and
an upper first P-side guide layer interposed between the P-side semiconductor layer and the P-type cladding layer, wherein
the active layer includes: a well layer comprising a nitride semiconductor; and a barrier layer comprising a nitride semiconductor including Al,
an average band gap energy of the P-side semiconductor layer is smaller than an average band gap energy of the P-type cladding layer, and
the P-side semiconductor layer is an optical guide layer comprising AlGaInN.

2. The nitride semiconductor light-emitting element according to claim 1, wherein
the upper first P-side guide layer comprises AlGaN.

3. The nitride semiconductor light-emitting element according to claim 1, further comprising:
an electron blocking layer interposed between the P-side semiconductor layer and the P-type cladding layer.

4. The nitride semiconductor light-emitting element according to claim 1, wherein
an Al composition ratio of the P-side semiconductor layer is higher than an Al composition ratio of the P-type cladding layer.

5. The nitride semiconductor light-emitting element according to claim 1, wherein
the P-side semiconductor layer has compressive strain, and
an average band gap energy of the P-side semiconductor layer is larger than a band gap energy of GaN.

6. The nitride semiconductor light-emitting element according to claim 5, wherein
an Al composition ratio of the P-side semiconductor layer is higher than an Al composition ratio of the barrier layer.

7. The nitride semiconductor light-emitting element according to claim 1, wherein
a lattice constant of the AlGaInN is greater than a lattice constant of GaN, and
a band gap energy of the AlGaInN is larger than a band gap energy of GaN.

8. The nitride semiconductor light-emitting element according to claim 1, wherein
the barrier layer comprises AlGaInN.

9. The nitride semiconductor light-emitting element according to claim 8, wherein
an In composition ratio of the P-side semiconductor layer is higher than an In composition ratio of the barrier layer.

10. The nitride semiconductor light-emitting element according to claim 8, wherein
an Al composition ratio of the P-side semiconductor layer is lower than or equal to an Al composition ratio of the barrier layer.

11. The nitride semiconductor light-emitting element according to claim 1, wherein
an average band gap energy of the P-side semiconductor layer is smaller than a band gap energy of the barrier layer.

12. The nitride semiconductor light-emitting element according to claim 11, wherein
an Al composition ratio of the P-side semiconductor layer is lower than an Al composition ratio of the barrier layer.

13. The nitride semiconductor light-emitting element according to claim 1, wherein
the well layer comprises AlGaInN.

14. The nitride semiconductor light-emitting element according to claim 1, further comprising:
an N-side semiconductor layer comprising a nitride semiconductor and disposed above the N-type cladding layer, wherein
an average band gap energy of the N-side semiconductor layer is smaller than an average band gap energy of the N-type cladding layer, and
the active layer is disposed above the N-side semiconductor layer.

15. The nitride semiconductor light-emitting element according to claim 14, wherein
the average band gap energy of the N-side semiconductor layer is smaller than a band gap energy of the barrier layer.

16. The nitride semiconductor light-emitting element according to claim 14, wherein
the N-side semiconductor layer is an optical guide layer.

17. The nitride semiconductor light-emitting element according to claim 14, wherein
the N-side semiconductor layer comprises AlGaInN.

18. The nitride semiconductor light-emitting element according to claim 14, wherein
the average band gap energy of the P-side semiconductor layer is smaller than the average band gap energy of the N-side semiconductor layer.

19. The nitride semiconductor light-emitting element according to claim 14, wherein
an In composition ratio of the P-side semiconductor layer is higher than an In composition ratio of the N-side semiconductor layer.

20. A nitride semiconductor light-emitting element comprising:
a substrate comprising GaN;
an N-type cladding layer comprising AlGaN and disposed above the substrate;
an active layer disposed above the N-type cladding layer;
a P-side semiconductor layer comprising a nitride semiconductor and disposed above the active layer;
a P-type cladding layer comprising AlGaN and disposed above the P-side semiconductor layer; and
an electron blocking layer interposed between the P-side semiconductor layer and the P-type cladding layer, wherein
the active layer includes: a well layer comprising a nitride semiconductor; and a barrier layer comprising a nitride semiconductor including Al,
an average band gap energy of the P-side semiconductor layer is smaller than an average band gap energy of the P-type cladding layer, and
the P-side semiconductor layer is an optical guide layer comprising AlGaInN.
